(19) United States
(12) Patent Application Publication
(10) Pub. No.: US 2026/0239759 A1
(43) Pub. Date: Aug. 13, 2026

(54) IMAGE SENSOR, METHOD OF MANUFACTURING THE SAME, AND ELECTRONIC DEVICE INCLUDING IMAGE SENSOR

(71) Applicant: SAMSUNG ELECTRONICS CO., LTD., Suwon-si (KR)

(72) Inventors: Hongkyu PARK, Suwon-si (KR); Sookyoung ROH, Suwon-si (KR); Hyeonsoo PARK, Suwon-si (KR); Minwoo LIM, Suwon-si (KR)

(73) Assignee: SAMSUNG ELECTRONICS CO., LTD., Suwon-si (KR)

(21) Appl. No.: 19/531,219

(22) Filed: Feb. 5, 2026

(30) Foreign Application Priority Data
Feb. 7, 2025 (KR) 10-2025-0016172

(51) Int. Cl. H10F 39/00

(52) U.S. Cl. CPC H10F 39/8057; H10F 39/024; H10F 39/8053; H10F 39/811

(57) ABSTRACT

An image sensor includes an active pixel sensor region outputting a pixel signal for generating images, and a peripheral region surrounding the active pixel sensor region, wherein the active pixel sensor region and the peripheral region include a sensor substrate including multiple pixels extending in the active pixel sensor region and the peripheral region, an optical-transparent layer arranged over the sensor substrate, separated from the sensor substrate, and including at least one dielectric material, and a planarization layer between the sensor substrate and the optical-transparent layer. In the active pixel sensor region, the optical-transparent layer includes a meta-optical element including multiple nanostructures, the peripheral region includes a light-shielding layer surrounding the active pixel sensor region between the planarization layer and the sensor substrate, and the peripheral region includes multiple holes penetrating the optical-transparent layer and exposing one of the planarization layer and the light-shielding layer.

### CROSS-REFERENCE TO RELATED APPLICATION

This application is based on and claims priority under 35 U.S.C. §119 to Korean Patent Application No. 10-2025-0016172, filed on February 07, 2025, in the Korean Intellectual Property Office, the disclosure of which is incorporated by reference herein in its entirety.

### BACKGROUND

### 1. Field

The disclosure relates to an image sensor, a method of manufacturing the image sensor, and an electronic device including the image sensor.

### 2. Description of Related Art

An image sensor detects light from a subject and converts the light into an electrical signal to obtain an image of the subject. An image sensor generally uses a color filter to distinguish and detect the color of incident light. However, a color filter absorbs light of colors other than the light of a color corresponding to the color filter, and thus, light utilization efficiency may be reduced. Accordingly, an image sensor utilizing a meta-optical element for distinguishing and detecting the color of incident light without using a color filter has been proposed recently.

The image sensor includes an active region for detecting light and a peripheral region surrounding the active region. The active region may include a meta-optical element that branches light from a subject for each color, and a peripheral region may include various circuit components and wires for signal processing. The peripheral region may also include a light-shielding layer that prevents the light from the components from being incident on the active region.

In the process of manufacturing the image sensor, before a meta-optical element is formed in the active region, a planarization thin film is formed on a sensor substrate to meet a distance requirement from the sensor substrate, and the planarization thin film extends from the active region to the peripheral region to cover the light-shielding layer.

The planarizing thin film and/or the light-shielding layer may include an organic material. However, the organic material has an issue of out-gassing in which residual gas, such as carbon or hydrogen, included in the organic material is released at a high temperature of approximately 200 degrees or more, and defects may occur due to this. Accordingly, a method of reducing defects due to gas release from an organic material is required.

### SUMMARY

Aspects of the disclosure provide an image sensor having a structure that may improve the reliability of a high-temperature process, a method of manufacturing the image sensor, and an electronic device including the image sensor.

Additional aspects will be set forth in part in the description which follows and, in part, will be apparent from the description, or may be learned by practice of the presented embodiments of the disclosure.

According to an aspect of the disclosure, there is provided an image sensor including: an active pixel sensor region configured to output a pixel signal; and a peripheral region surrounding the active pixel sensor region; wherein the active pixel sensor region and the peripheral region may include: a sensor substrate including a plurality of pixels extending in the active pixel sensor region and the peripheral region; an optical-transparent layer provided on the sensor substrate, the optical-transparent layer including at least one dielectric material; and a planarization layer provided between the sensor substrate and the optical-transparent layer, wherein, in the active pixel sensor region, the optical-transparent layer includes a meta-optical element including a plurality of nanostructures, and wherein the peripheral region may include: a light-shielding layer surrounding the active pixel sensor region between the planarization layer and the sensor substrate, and a plurality of holes penetrating the optical-transparent layer and exposing one of the planarization layer and the light-shielding layer.

The peripheral region may further include: an optical black region defined by the light-shielding layer, and a contact pad region surrounding the optical black region and including a plurality of contact pads, and wherein, in the contact pad region, the optical-transparent layer has a shape having a step difference.

The planarization layer may include: a first planarization layer including an organic material, and a second planarization layer arranged on the first planarization layer and including an inorganic material.

Each of the plurality of holes may have a depth that penetrates the second planarization layer and the first planarization layer, wherein each of the plurality of holes are configured to expose an upper surface of the light-shielding layer.

The light-shielding layer may include an organic material.

Each of the plurality of holes may have a depth that penetrates the second planarization layer, and wherein each of the plurality of holes are configured to expose an upper surface of the first planarization layer.

The light-shielding layer may include: a first layer including a light-reflecting material, and a second layer arranged on the first layer and including a light-absorbing material.

The active pixel sensor region may further include a color filter array layer arranged between the sensor substrate and the first planarization layer.

The light-shielding layer may include: a first layer including one of a light-reflecting material and a light-absorbing material, and a second layer arranged on the first layer and including a blue filter material.

An optical black region in the peripheral region may be defined by the light-shielding layer, and a total of cross-sectional areas of the plurality of holes is greater than or equal to 5 % of a cross-sectional area of the optical black region and less than or equal to 50 % of the cross-sectional area of the optical black region.

The active pixel sensor region may have a quadrangle shape, and the plurality of holes are formed at positions facing at least two of four sides of the quadrangle shape.

Each of the plurality of holes may have one of a circular shape, an oval shape, a square shape, a rectangular shape, and a polygonal shape.

The active pixel sensor region may have a quadrangle shape, and each of the plurality of holes has a stripe shape parallel to one side of the quadrangle shape.

Each of the plurality of holes may have a shape of a grid pattern.

The plurality of nanostructures may be arranged in a plurality of layers with different distances from the sensor substrate.

According to another aspect of the disclosure, there is provided a method of manufacturing an image sensor, the method including: forming a sensor substrate including a plurality of pixels, the sensor substrate having an active pixel sensor region and a peripheral region surrounding the active pixel sensor region; forming a light-shielding layer on the sensor substrate in the peripheral region; forming a planarization layer on the sensor substrate and the light-shielding layer, the planarization layer extending from the active pixel sensor region to the peripheral region and cover the light-shielding layer; forming an optical-transparent layer on the planarization layer to include at least one dielectric material; and forming a plurality of holes, which penetrate the optical-transparent layer and expose one of the planarization layer and the light-shielding layer, in the peripheral region.

The peripheral region may include an optical black region defined as a region where the light-shielding layer is formed, and a contact pad region surrounding the optical black region and including a plurality of contact pads, and before the forming of the optical-transparent layer, the method may include partially removing a portion of the planarization layer which extends to the contact pad region is performed.

The forming of the planarization layer may include: forming a first planarization layer including an organic material; and forming, on the first planarization layer, a second planarization layer including an inorganic material.

Each of the plurality of holes may have a depth that penetrates the first planarization layer and the second planarization layer to expose an upper surface of the light-shielding layer, or penetrates the second planarization layer to expose an upper surface of the first planarization layer.

According to another aspect of the disclosure, there is provided an electronic device including: a lens assembly configured to form an optical image of a subject; and an image sensor configured to convert the optical image formed by the lens assembly into an electrical signal, wherein the image sensor includes: an active pixel sensor region configured to output a pixel signal; and a peripheral region surrounding the active pixel sensor region, wherein the active pixel sensor region and the peripheral region include: a sensor substrate including a plurality of pixels extending in the active pixel sensor region and the peripheral region; an optical-transparent layer provided on the sensor substrate, the optical-transparent layer including at least one dielectric material; and a planarization layer provided between the sensor substrate and the optical-transparent layer, wherein, in the active pixel sensor region, the optical-transparent layer includes a meta-optical element including a plurality of nanostructures, and wherein the peripheral region includes: a light-shielding layer surrounding the active pixel sensor region between the planarization layer and the sensor substrate, and a plurality of holes penetrating the optical-transparent layer and exposing one of the planarization layer and the light-shielding layer.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a block diagram of an image sensor according to an embodiment;

FIG. 2 is a plan view illustrating the arrangement of multiple regions that have different functions and are included in an image sensor according to an embodiment;

FIG. 3 is a cross-sectional view taken along line A-A' of the image sensor illustrated in FIG. 2;

FIG. 4 is a cross-sectional view of an image sensor according to another embodiment;

FIG. 5 is a cross-sectional view of an image sensor according to another embodiment;

FIG. 6 is a plan view of an image sensor according to another embodiment;

FIG. 7 is a plan view of an image sensor according to another embodiment;

FIG. 8 is a plan view of an image sensor according to another embodiment;

FIG. 9 is a plan view of an image sensor according to another embodiment;

FIG. 10 is a plan view of an image sensor according to another embodiment;

FIG. 11 is a plan view of an image sensor according to another embodiment;

FIG. 12 is a cross-sectional view of an image sensor according to another embodiment;

FIG. 13 is a cross-sectional view of an image sensor according to another embodiment;

FIG. 14 is a flowchart schematically illustrating a method of manufacturing an image sensor, according to an embodiment;

FIG. 15 is a block diagram schematically illustrating an electronic device including an image sensor according to an embodiment;

FIG. 16 is a block diagram schematically illustrating a camera module included in the electronic device of FIG. 15;

FIG. 17 is a block diagram of an electronic device including multiple camera modules; and

FIG. 18 is a detailed block diagram of one camera module included in the electronic device of FIG. 17.

### DETAILED DESCRIPTION

Reference will now be made in detail to embodiments, examples of which are illustrated in the accompanying drawings, wherein like reference numerals refer to like elements throughout. In this regard, the embodiments of the disclosure may have different forms and should not be construed as being limited to the descriptions set forth herein. Accordingly, the embodiments are merely described below, by referring to the figures, to explain aspects. As used herein, the term "and/or" includes any and all combinations of one or more of the associated listed items. Expressions such as "at least one of," when preceding a list of elements, modify the entire list of elements and do not modify the individual elements of the list.

Hereinafter, embodiments are described in detail with reference to the attached drawings. The embodiments to be described below are merely illustrative, and various modifications may be made from the embodiments. In the drawings, like reference numerals refer to like elements, and a size of each element in the drawings may be exaggerated for clarity and convenience of description.

Hereinafter, the term "above", "over", or "on" may include not only what is directly above in contact but also what is above without contact.

The terms "first", "second", and so on may be used to describe various configuration elements but are used only for the purpose of distinguishing one configuration element from another configuration element. The terms do not limit the difference in material or structure of the configuration elements.

A singular expression includes plural expressions unless the context clearly indicates otherwise. In addition, when a part is described to "include" a certain configuration element, which means that the part may further include other configuration elements, except to exclude other configuration elements unless otherwise stated.

Also, terms such as "unit", "portion", and "module" described in the specification may indicate units that process at least one function or operation, which may be configured by hardware, software, or a combination of hardware and software.

Use of the term "above-described" and a similar reference term may correspond to both the singular and the plural.

Operations constituting a method are not limited in the order described and may be performed in any suitable order unless there is a clear statement that the operations should be performed in the order described. Also, use of all example terms ("for example" and "and so on") is merely for describing technical ideas in detail, and the scope of the claims are not limited to the terms unless limited by claims.

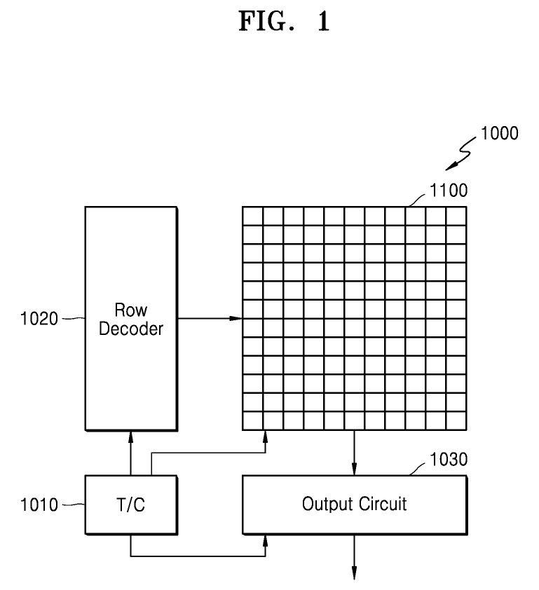

FIG. 1 is a block diagram of an image sensor according to an embodiment.

Referring to FIG. 1, an image sensor 1000 may include a pixel array 1100, a timing controller (T/C) 1010, a row decoder 1020, and an output circuit 1030. The image sensor may be a charge-coupled device (CCD) image sensor or a complementary metal oxide semiconductor (CMOS) image sensor.

The pixel array 1100 may include pixels arranged two-dimensionally along multiple rows and columns. The row decoder 1020 may select one of the multiple rows of the pixel array 1100 based on a row address signal output from the timing controller 1010. For example, in response to the row address signal output from the timing controller 1010, the row decoder 1020 may select one of the multiple rows of the pixel array 1100. The output circuit 1030 outputs a photo detection signal from the pixels arranged along a selected row in units of columns. According to an embodiment, in order to output the photo detection signal from the pixels, the output circuit 1030 may include a column decoder and an analog-to-digital converter (ADC). For example, the output circuit 1030 may include multiple ADCs arranged for each column between a column decoder and the pixel array 1100, or one ADC arranged at an output terminal of the column decoder. The timing controller 1010, the row decoder 1020, and the output circuit 1030 may be integrated into one chip or may be respectively included in different chips. A processor for processing an image signal output through the output circuit 1030 may be included in a chip integrated with the timing controller 1010, the row decoder 1020, and the output circuit 1030.

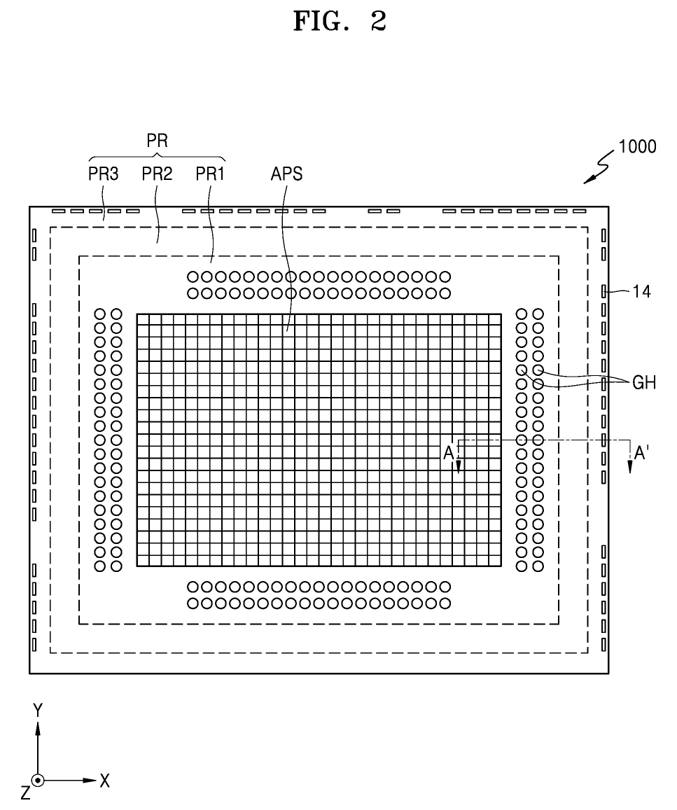

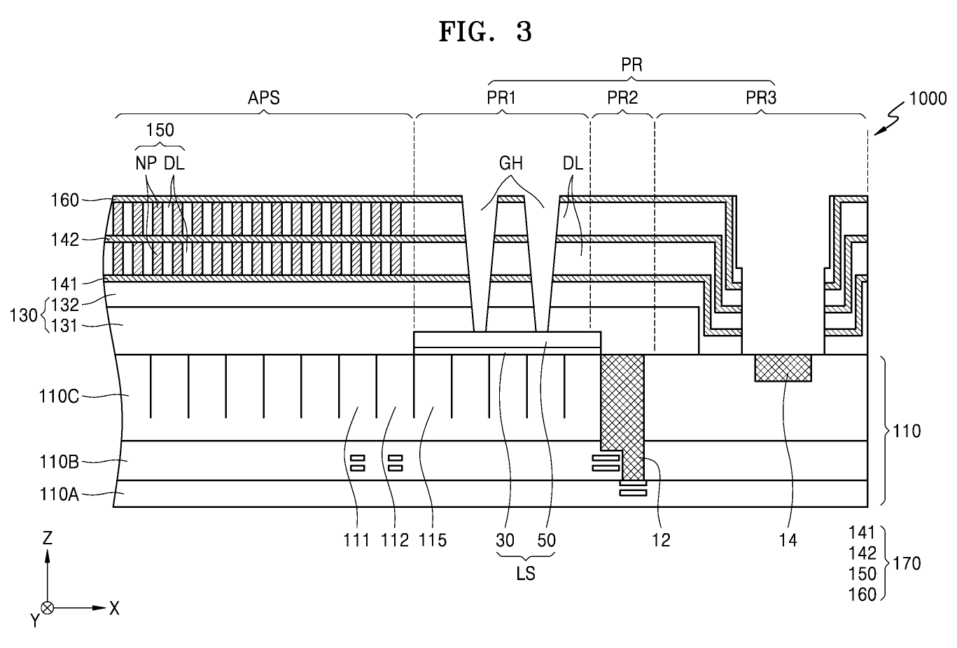

The image sensor 1000 may include multiple regions having different functions. FIG. 2 is a plan view illustrating the arrangement of multiple regions, which have different functions and are provided in an image sensor according to an embodiment, and FIG. 3 is a cross-sectional view taken along line A-A' of the image sensor 1000 illustrated in FIG. 2.

Referring to FIGS. 2 and 3, the image sensor 1000 may include an active pixel sensor region APS and a peripheral region PR. The active pixel sensor region APS may output a pixel signal for generation of an image and the peripheral region PR may be arranged to surround the periphery of the active pixel sensor region APS. The peripheral region PR may include multiple regions. For example, the peripheral region PR may include an optical black region PR1 surrounding the periphery of the active pixel sensor region APS, a back via stack region PR2 surrounding the periphery of the optical black region PR1, and a contact pad region PR3 surrounding the periphery of the back via stack region PR. The optical black region PR1 may output a dark signal. The back via stack region PR2 may include wires for electrical connection between upper and lower layers in the image sensor 1000. The contact pad region PR3 may include multiple contact pads 14 for signal input/output with the outside of the image sensor 1000.

The active pixel sensor region APS is a region where pixels that output signals for image generation are formed. For example, the signals output by the active pixel sensor region APS may be directly used for forming an image. The active pixel sensor region APS may correspond to the pixel array 1100 illustrated in FIG. 1. The active pixel sensor region APS may be arranged at the center portion of the image sensor 1000. Some or all of the pixels included in the active pixel sensor region APS may detect light having a certain wavelength band, that is, light of a certain color, among beams of light incident on the active pixel sensor region APS, and output the intensity of the color component included in the incident light. The active pixel sensor region APS may include three or more types of pixels. For example, the active pixel sensor region APS may include a green pixel that detects the intensity of a green light component from incident light, a red pixel that detects the intensity of a red light component from the incident light, and a blue pixel that detects the intensity of a blue light component from the incident light. The image sensor 1000 may generate an image by using signals output by the pixels arranged in the active pixel sensor region APS, and higher the resolution of an image may be generated as the number of pixels in the active pixel sensor region APS increases.

The optical black region PR1 is a region where the pixels, which output pixel signals without incident light, that is, dark signals, are formed. The optical black region PR1 may surround the periphery of the active pixel sensor region APS. A light-shielding layer LS that blocks incident light may be arranged in the optical black region PR1, and the light-shielding layer LS may surround the active pixel sensor region APS. For example, the optical black region PR1 may be defined by the light-shielding layer LS surrounding the active pixel sensor region APS. The optical black region PR1 includes pixels that detect light, similarly to the active pixel sensor region APS. However, since the light-shielding layer LS blocks the light incident on the pixels, the pixels in the optical black region PR1 do not output pixel signals for image generation. The pixels arranged in the optical black region PR1 may output a dark signal, which is a noise signal generated by a material forming a photodiode included in the pixel or a pixel structure, in a state where light is blocked from being incident on the pixel. The dark signal may be used as a reference signal for noise correction of a pixel signal output from an active pixel sensor region APS.

According to an embodiment, multiple holes GH may be formed in the optical black region PR1. The multiple holes GH may be formed to release organic gas due to an organic material among materials forming the image sensor 1000. For example, organic gas generated by organic material among materials forming the image sensor 1000 may be released through the multiple holes GH. The multiple holes GH may prevent noise in a surrounding region from being transmitted to the active pixel sensor region APS. For example, the multiple holes GH may also prevent noise light, which is not blocked by the light-shielding layer LS, from being transmitted to the active pixel sensor region APS. The multiple holes GH may surround the active pixel sensor region APS. The active pixel sensor region APS may have a quadrangle shape, for example, a rectangular shape as illustrated in FIG. 2, and the multiple holes GH may face at least one of four sides of the quadrangle shape, for example, the rectangular shape. As illustrated in FIG. 2, the multiple holes GH may face the four sides of the rectangular shape. However, this is an example, and the multiple holes GH may be formed at positions facing two or three sides of the rectangular shape or formed at a position facing one side of the rectangular shape.

However, the disclosure is not limited thereto, and as such, a number of number and/or shapes of the multiple holes GH may be different than illustrated in FIGS. 2 and 3. For example, the number or shapes of the multiple holes GH may be determined by considering the release efficiency of organic gas or a process condition. For example, the total area of the multiple holes GH illustrated in the plan view of FIG. 2 may be greater than or equal to 5 % and less than or equal to 50 % of the area of the optical black region PR1. However, this is an example, and the embodiment is not limited thereto.

For example, the shape of each of the multiple holes GH may be a circular shape. However, this is an example, and in some embodiments, the multiple holes GH may each have a square shape, an elliptical shape, or one of various polygonal shapes.

According to an embodiment, the back via stack region PR2 may include multiple back via stacks 12 for electrical connection between upper and lower layers in the image sensor 1000. The back via stack region PR2 may surround the periphery of the optical black region PR1. The multiple back via stacks 12 may be arranged with an interval from the optical black region PR1 within the back via stack region PR2. The back via stacks 12 may be provided in multiple pieces, that is, the back via stacks 12 may be provided at positions other than a cross-section A-A' illustrated in FIG. 2. The back via stack 12 may have a shape that is long in the first direction (that is, the X direction) or the second direction (that is, the Y direction) while facing one side of the optical black region PR1, and the multiple back via stacks 12 may be arranged at intervals in the first direction or the second direction.

According to an embodiment, the contact pad region PR3 may include the multiple contact pads 14 for signal input/output between the image sensor 1000 and an external device. The contact pad region PR3 may surround the periphery of the back via stack region PR2. The number and positions of the multiple contact pads 14 are not limited to the number and positions illustrated in the drawings and may be variously selected depending on design needs. The multiple contact pads 14 may be electrically connected to input/output circuits included in the image sensor 1000.

As illustrated in FIG. 3, the active pixel sensor region APS and the peripheral region PR, that is, the active pixel sensor region APS, the optical black region PR1, the back via stack region PR2, and the contact pad region PR3, may commonly include a sensor substrate 110, a planarization layer 130, and an optical-transparent layer 170. According to an embodiment, the optical-transparent layer 170 may include a meta-optical element 150, a dielectric layer DL, etching stop layers 141 and 142, and an anti-reflection layer 160. For example, the meta-optical element 150 including multiple nanostructures NP and the dielectric layer DL, the dielectric layer DL, the etching stop layers 141 and 142, and the anti-reflection layer 160, each extended from the active pixel sensor region APS to the peripheral region PR, may form an optical-transparent layer 170. However, the disclosure is not limited thereto, and as such, according to another embodiment, one or more layers may added, omitted or combined in the optical transparent layer 170. For example, the multiple nanostructures NP and the dielectric layer DL are provided in the active pixel sensor region APS.

The sensor substrate 110 may extend in the active pixel sensor region APS, the optical black region PR1, the back via stack region PR2, and the contact pad region PR3. On inner and upper surfaces of the sensor substrate 110, the active pixel sensor region APS, the optical black region PR1, the back via stack region PR2, and the contact pad region PR3 may have different layer structures.

The sensor substrate 110 may include multiple layers having different functions, which are stacked in the third direction (the Z direction). For example, the sensor substrate 110 may include a lower chip 110A, an upper chip 110B on the lower chip 110A, and a sensor layer 110C on the upper chip 110B. The lower chip 110A, the upper chip 110B, and the sensor layer 110C may extend in the active pixel sensor region APS and the peripheral region PR. For example, the lower chip 110A, the upper chip 110B, and the sensor layer 110C may extend in the active pixel sensor region APS, the optical black region PR1, the back via stack region PR2, and the contact pad region PR3. According to an embodiment, a logic circuit for driving the image sensor 1000 may be on the lower chip 110A. For example, the timing controller 1010 and the row decoder 1020 illustrated in FIG. 1 may be in the lower chip 110A. According to an embodiment, a processor may be in the lower chip 110A. in an example, the processor may be provided in additional to the timing controller 1010 and the row decoder 1020. The upper chip 110B may include circuits for outputting signals from the sensor layer 110C. For example, the output circuit 1030 illustrated in FIG. 1 may be in the upper chip 110B. Also, an amplifier circuit for amplifying signals may be in the upper chip 110B. According to an embodiment, multiple photosensitive elements that convert incident light into electrical signals may be in the sensor layer 110C. For example, the sensor layer 110C may include multiple photodiodes.

According to an embodiment, the active pixel sensor region APS may include the planarization layer 130 on an upper surface of the sensor substrate 110, and the meta-optical element 150 on the planarization layer 130. The planarization layer 130 and the meta-optical element 150 may be sequentially stacked on the sensor substrate 110 in the third direction (the Z direction). Therefore, the meta-optical element 150 may face the sensor layer 110C of the sensor substrate 110 with the planarization layer 130 between the meta-optical element 150 and the sensor layer 110C. The active pixel sensor region APS may further include the etching stop layer 141 between the planarization layer 130 and the meta-optical element 150, and the etching stop layer 142 between nanostructures NP forming different layers. The active pixel sensor region APS may further include the anti-reflection layer 160 on an upper surface of the meta-optical element 150.

According to an embodiment, in the active pixel sensor region APS, the sensor layer 110C of the sensor substrate 110 may include multiple pixels 111 and 112 arranged two-dimensionally in the first direction (the X direction) and the second direction (the Y direction). The multiple pixels 111 and 112 may each include a photodiode. The meta-optical element 150 may separate incident light for each wavelength and/or collect incident light and provide light to each of the multiple pixels 111 and 112. For example, in order to separate the incident light and provide the light to each of the multiple pixels 111 and 112. the meta-optical element 150 may include the multiple nanostructures NP arranged to have a preset meta-pattern and the dielectric layer DL filled between the multiple nanostructures NP. The multiple nanostructures NP may each include a material having a higher refractive index than a refractive index of a material of the dielectric layer DL. Although FIG. 3 illustrates that the multiple nanostructures NP included in the meta-optical element 150 are arranged in two layers, this is an example, and the multiple nanostructures NP may be arranged in a single layer or in multiple layers of two or more layers.

The planarization layer 130, the etching stop layers 141 and 142, the dielectric layer DL, and the anti-reflection layer 160 included in the active pixel sensor region APS may extend integrally from the active pixel sensor region APS to the peripheral region PR. For example, the planarization layer 130, the etching stop layers 141 and 142, the dielectric layer DL, and the anti-reflection layer 160 included in the active pixel sensor region APS may extend from the active pixel sensor region APS to the optical black region PR1, the back via stack region PR2, and the contact pad region PR3.

The optical black region PR1 may include the light-shielding layer LS on an upper surface of the sensor substrate 110, particularly the sensor layer 110C, the planarization layer 130 configured to cover the light-shielding layer LS, and the dielectric layer DL on the planarization layer 130. The light-shielding layer LS may include a material that blocks light from being incident on the sensor layer 110C. The light-shielding layer LS may include a single layer or multiple material layers. The light-shielding layer LS may include an organic material. The light-shielding layer LS may include, for example, a first layer 30 including a light-reflecting material and a second layer 50 including a light-absorbing material. The second layer 50 may be on the first layer 30. The light-reflecting material included in the first layer 30 may include one of various metal materials. For example, the light-reflecting material included in the first layer 30 may include, but is not limited to, chromium, copper, tungsten, nickel, and aluminum. The light-absorbing material included in the second layer 50 may include, but is not limited to, amorphous carbon (a-C). The second layer 50 may also include an organic material that absorbs light. Although FIG. 3 illustrates that the second layer 50 is directly on an upper surface of the first layer 30, the disclosure is not limited thereto, and as such, according to an embodiment, an interlayer material may be arranged between the first layer 30 and the second layer 50. For example, the interlayer material may be provided by considering the necessity of a manufacturing process or light shielding efficiency.

The light-shielding layer LS may be formed entirely on the optical black region PR1. The anti-reflection layer 160, the dielectric layer DL, the etching stop layers 141 and 142, and the planarization layer 130 are optically transparent, and the light-shielding layer LS may prevent the light transmitting through the material layers from being incident on the sensor layer 110C. For example, the optical black region PR1 may be substantially implemented by the light-shielding layer LS.

According to an embodiment, in the optical black region PR1, the sensor layer 110C of the sensor substrate 110 may include multiple pixels 115 arranged two-dimensionally in the first direction and the second direction. The light-shielding layer LS may cover the multiple pixels 115. Therefore, the light incident on the optical black region PR1 may not reach the multiple pixels 115, and the multiple pixels 115 in the optical black region PR1 may output dark signals.

The planarization layer 130 may have a thickness that is suitable for a distance requirement between the sensor substrate 110 and the meta-optical element 150, and may have a flat upper surface for forming the meta-optical element 150. The planarization layer 130 may be formed by, for example, a spin coating method. The planarization layer 130 may include a material that is transparent to visible light. The planarization layer 130 may include a dielectric material or an organic material having a lower refractive index than the nanostructure NP and a low absorption rate in a visible light band.

The planarization layer 130 may include a first planarization layer 131 and a second planarization layer 132. The first planarization layer 131 may include an organic material that is transparent to visible light and may include, for example, an organic polymer material. The organic polymer material may include but is not limited to, epoxy resin, polyimide, polycarbonate, polyacrylate, polymethyl methacrylate (PMMA), or siloxane-based spin on glass (SOG). The first planarization layer 131 may be formed by, for example, a spin coating method and may have a flat upper surface through heat treatment.

The second planarization layer 132 may be on the first planarization layer 131. The second planarization layer 132 may serve as a protective layer that prevents the first planarization layer 131 formed of an organic polymer material from being damaged during a process of forming the meta-optical element 150 on the first planarization layer 131. The second planarization layer 132 may include an inorganic material. An inorganic material of the second planarization layer 132 may be formed at a temperature lower than a process temperature for forming the meta-optical element 150 and may include a material transparent to visible light. According to an embodiment, in order to reduce reflection loss at an interface between the first planarization layer 131 and the second planarization layer 132, it may be advantageous that a refractive index of the second planarization layer 132 is similar to a refractive index of the first planarization layer 131. For example, the difference between the refractive index of the first planarization layer 131 and the refractive index of the second planarization layer 132 may be within ±20 % of the refractive index of the first planarization layer 131. The second planarization layer 132 may include, but is not limited to, SiO₂, SiN, Al₂O₃, or SiON.

The planarization layer 130 is elongated from the active pixel sensor region APS to the optical black region PR1, and the optical-transparent layer 170 including the etching stop layers 141 and 142, the dielectric layer DL, and the anti-reflection layer 160 may be formed on the planarization layer 130 of the optical black region PR1. The multiple nanostructures NP may not be provided in the dielectric layer DL in the optical black region PR1. A crack stopper having the same material and thickness as each of the multiple nanostructures NP may also be formed in the dielectric layer DL in the optical black region PR1.

The multiple holes GH, which penetrate the optical-transparent layer 170 and expose the planarization layer 130, may be formed in the optical black region PR1. As illustrated in FIG. 3, the multiple holes GH may each have a depth that penetrates the anti-reflection layer 160, the meta-optical element 150, the etching stop layers 141 and 142, the second planarization layer 132, and the first planarization layer 131. A cross-sectional area of each of the multiple holes GH may decrease in a depth direction. For example, as illustrated in FIG. 3, a width of each of the multiple holes GH in the first direction (the X direction) and the width of each of the multiple holes GH in the second direction (the Y direction) may decrease as a depth position increases. This shape may be generally formed by an etching process of forming the multiple holes GH but is not limited to the illustrated shape.

The multiple holes GH may expose an upper surface of the light-shielding layer LS and may also expose side surfaces of the first planarization layer 131 and the second planarization layer 132. The multiple holes GH may be provided for out-gassing of an organic material included in the planarization layer 130 or the light-shielding layer LS.

In a state where the multiple holes GH are not formed, the planarization layer 130 and the light-shielding layer LS may be completely sealed by various dielectric materials forming the optical-transparent layer 170, that is, the etching stop layers 141 and 142, the dielectric layer DL, the multiple nanostructures NP, and the anti-reflection layer 160. The organic material may release residual gas, such as carbon or hydrogen in the organic material at a high temperature of about 200 degrees or more. Such a high temperature process may be included in a process of forming the meta-optical element 150. Gas release from the sealed organic material may cause defects, such as bubbles or cracks.

The image sensor 1000 of the embodiment having the multiple holes GH exposing the planarization layer 130 or the light-shielding layer LS may prevent defects caused by organic gas by releasing the organic gas generated in the high temperature process through the multiple holes GH.

The back via stack region PR2 may include one or more back via stacks 12 extending in the third direction (the Z direction) within the sensor substrate 110. The back via stacks 12 may extend in the third direction along the lower chip 110A, the upper chip 110B, and the sensor layer 110C to electrically connect between circuits or elements of the lower chip 110A and the upper chip 110B, between circuits or elements of the upper chip 110B and the sensor layer 110C, or between circuits or elements of the lower chip 110A and the sensor layer 110C.

The light-shielding layer LS of the optical black region PR1 may extend to a part of the back via stack region PR2. Therefore, light incident obliquely on the back via stack region PR2 may be prevented from being incident on the multiple pixels 115 in the optical black region PR1 by the light-shielding layer LS.

The back via stack region PR2 may also include the planarization layer 130, the etching stop layers 141 and 142 on the planarization layer 130, the dielectric layer DL, and the anti-reflection layer 160. The planarization layer 130, the etching stop layers 141 and 142, the dielectric layer DL, and the anti-reflection layer 160 in the back via stack region PR2 may integrally extend from the active pixel sensor region APS in the first direction and the second direction. In the back via stack region PR2, the planarization layer 130 may be in direct contact with a part of an upper surface of the sensor substrate 110 and the upper surfaces of the multiple back via stacks 12. Also, the multiple nanostructures NP may not be formed in the dielectric layer DL in the back via stack region PR2.

The contact pad region PR3 may include the multiple contact pads 14 on an upper surface of the sensor substrate 110. The multiple contact pads 14 may be electrically connected to input/output circuits in the image sensor 1000. For example, the multiple contact pads 14 may be electrically connected to circuits or elements in the lower chip 110A, the upper chip 110B, or the sensor layer 110C. The multiple contact pads 14 may be arranged on the upper surface of the sensor substrate 110 or may also be embedded within the upper surface of the sensor substrate 110.

In order to form the multiple contact pads 14, the planarization layer 130, the etching stop layers 141 and 142, the dielectric layer DL, and the anti-reflection layer 160 may be etched in the contact pad region PR3. That is, the planarization layer 130, the etching stop layers 141 and 142, the dielectric layer DL, and the anti-reflection layer 160 may extend only to a part of the contact pad region PR3. Shapes in which the etching stop layers 141 and 142, the dielectric layer DL, and the anti-reflection layer 160 are etched in the contact pad region PR3 may be, for example, a hole shape that partially exposes an upper surface of an edge of the sensor substrate 110, as illustrated in FIG. 3. The multiple contact pads 14 may be in the exposed upper surface of the sensor substrate 110.

The optical-transparent layer 170 including the etching stop layers 141 and 142, the dielectric layer DL and the anti-reflection layer 160 in the contact pad region PR3 may have a stepped shape, as illustrated in FIG. 3. The stepped shape may be due to a manufacturing process below. In order to form the contact pad region PR3, the planarization layer 130 may be formed entirely in the active pixel sensor region APS and the peripheral region PR on the sensor substrate 110, and then, before the optical-transparent layer 170 including the meta-optical element 150 is formed on the planarization layer 130, a process of removing a part of the planarization layer 130 extending to the contact pad region PR3 by etching may be performed. In this way, as the optical-transparent layer 170 is formed on a step difference formed between the planarization layer 130 and the sensor substrate 110, the optical-transparent layer 170 has a stepped shape in the contact pad region PR3.

In a comparative example case in which the optical-transparent layer 170 is formed on the planarization layer 130 without etching a part of the planarization layer 130 in advance, a process of etching the optical-transparent layer 170 and the planarization layer 130 together is performed to expose an upper surface of the sensor substrate 110 in the contact pad region PR3 to form the contact pad 14. In this example case, because an etching rate of a dielectric material included in the optical-transparent layer 170 is less than an etching rate of an organic material included in the planarization layer 130, a defect that a structure around the contact pad 14 collapses may occur. According to an embodiment of the disclosure, in an example case in which a part of the planarization layer 130 in the contact pad region PR3 is removed in advance, a structure etched in the process of exposing the sensor substrate 110 to form the contact pad 14 may not include an organic material but may include a dielectric material, and thus, defects may not occur.

In the back via stack region PR2 and the contact pad region PR3, a photodiode may not be formed in the sensor layer 110C. For example, the back via stack region PR2 and the contact pad region PR3 may not include pixels that detect light. Although FIG. 3 illustrates that thicknesses of the sensor substrates 110, particularly thicknesses of the sensor layers 110C in the back via stack region PR2, the contact pad region PR3, the active pixel sensor region APS, and the optical black region PR1 are equal to each other, the disclosure is not limited thereto. For example, because there is no photodiode in the sensor layer 110C in the back via stack region PR2 and the contact pad region PR3, thicknesses of the sensor layers 110C in the back via stack region PR2 and the contact pad region PR3 may be less than thicknesses of the sensor layers 110C in the active pixel sensor region APS and the optical black region PR1. In this case, there may be a step difference between the optical black region PR1 and the back via stack region PR2.

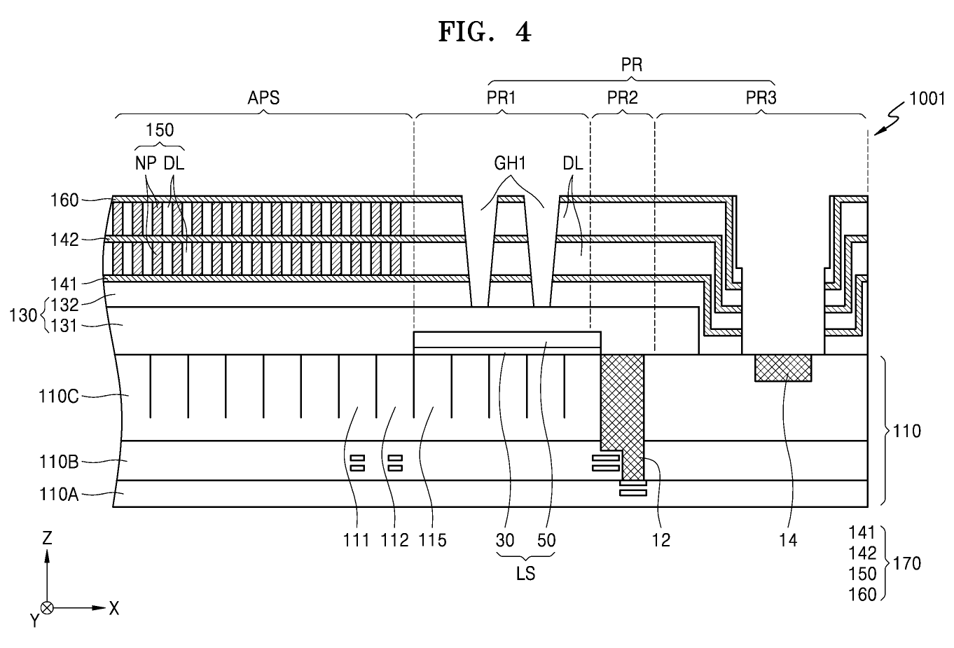

FIG. 4 is a cross-sectional view of an image sensor according to another embodiment.

FIG. 4 illustrates an image sensor 1001, which may differ from the image sensor 1000 described with reference to FIG. 3 in depths of multiple holes GH1 formed in an optical black region PR1.

The multiple holes GH1 may each have a depth that penetrates an optical-transparent layer 170 and a second planarization layer 132. For example, an upper surface of a first planarization layer 131 may be exposed by the multiple holes GH1, and a light-shielding layer LS may be covered by the first planarization layer 131 and may not be exposed.

According to an embodiment, the structure illustrated in FIG. may be used, for example, when the light-shielding layer LS does not include an organic material. However, the disclosure is not limited thereto.

Although FIG. 4 illustrates that a lower surface of the hole GH1 is parallel to an upper surface of the first planarization layer 131, this is an example, and the disclosure is not limited thereto. For example, a part of the first planarization layer 131 may be etched in a process of forming the hole GH1.

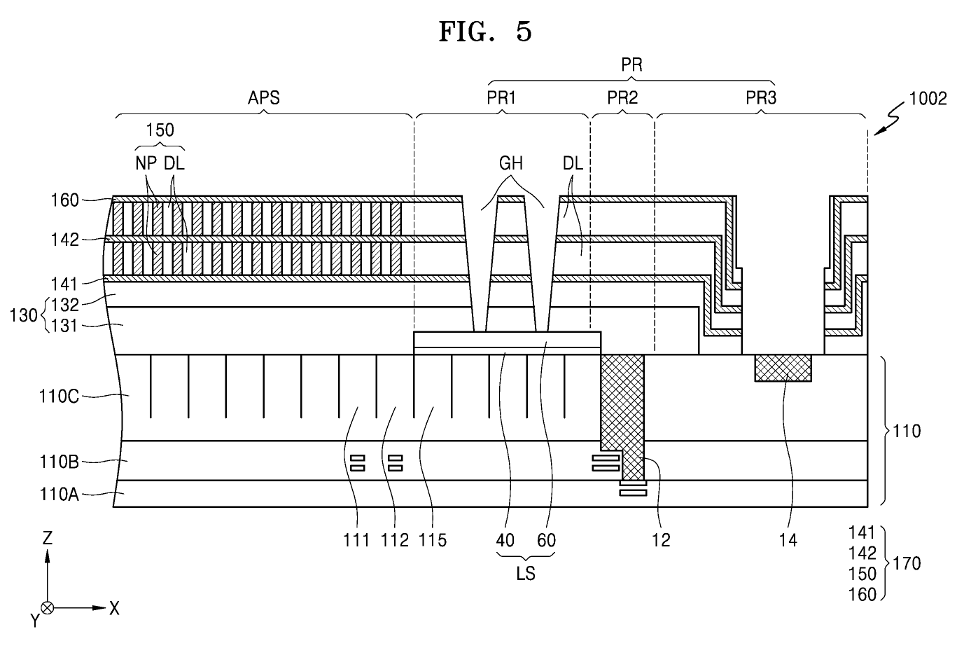

FIG. 5 is a cross-sectional view of an image sensor according to another embodiment.

FIG. 5 illustrates an image sensor 1002, which may differ from the image sensor 1000 of FIG. 3 in material of a light-shielding layer LS.

The light-shielding layer LS may include a first layer 40 including a material that absorbs or reflects light, and a second layer 60 including a blue filter material. The first layer 40 may include a material that reflects or absorbs visible light. The first layer 40 may include, but is not limited to, chromium, copper, tungsten, manganese dioxide, carbon black, graphite, or so on. The blue filter material of the second layer 60 may include a blue organic dye or pigment. According to an embodiment, a color filter may be included in an active pixel sensor region APS, and the blue filter material of the second layer 60 of the light-shielding layer LS may be a part of the color filter material described above. Although FIG. 5 illustrates that the second layer 60 including the blue filter material is directly on an upper surface of the first layer 40, an interlayer material may also be further arranged between the first layer 40 and the second layer 60 by considering the necessity of a manufacturing process or the light shielding efficiency.

In general, blue light having a relatively short wavelength is easily absorbed and has a relatively short propagation distance, while green light or red light having a relatively long wavelength has a relatively long propagation distance. Therefore, the second layer 60 including a blue filter material may absorb the green light and red light such that the green light or red light reflected without being absorbed by the first layer 40 is not incident on the pixels 111 and 112 in an active pixel sensor region APS.

Multiple holes GH formed in an optical black region PR1 may each have a depth that exposes a first planarization layer 131 including an organic material and the light-shielding layer LS.

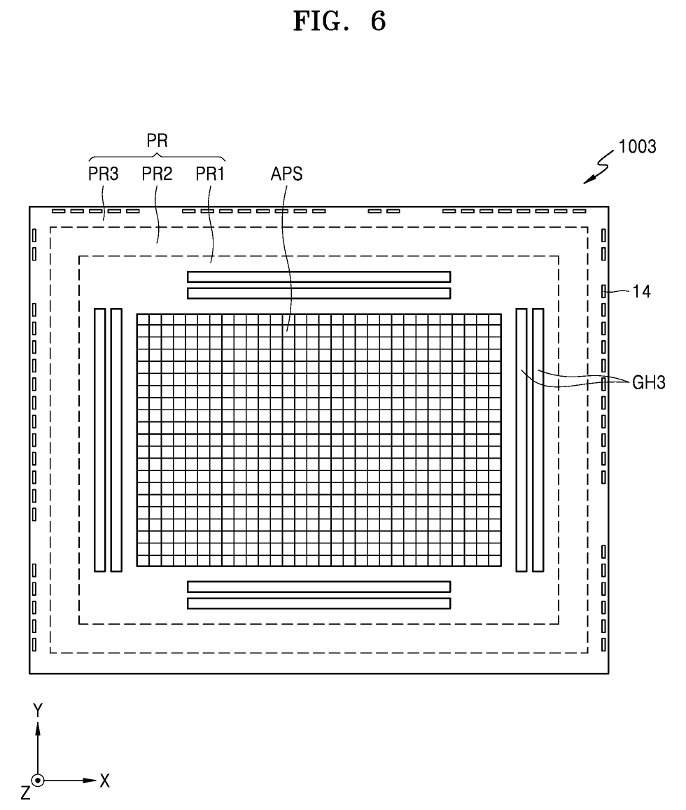

FIGS. 6 to 11 are plan views illustrating image sensors, each having multiple holes having various shapes.

Referring to FIG. 6, an image sensor 1003 may include multiple holes GH3, each having a stripe shape and being formed in an optical black region PR1.

An active pixel sensor region APS may have a quadrangle shape, and the multiple holes GH3 may each have a cross-sectional shape that is parallel to one of four sides of the quadrangle shape. Although FIG. 6 illustrates that each of four sides of the active pixel sensor region APS faces two holes GH3 having stripe shapes, the number of holes GH3 may be changed.

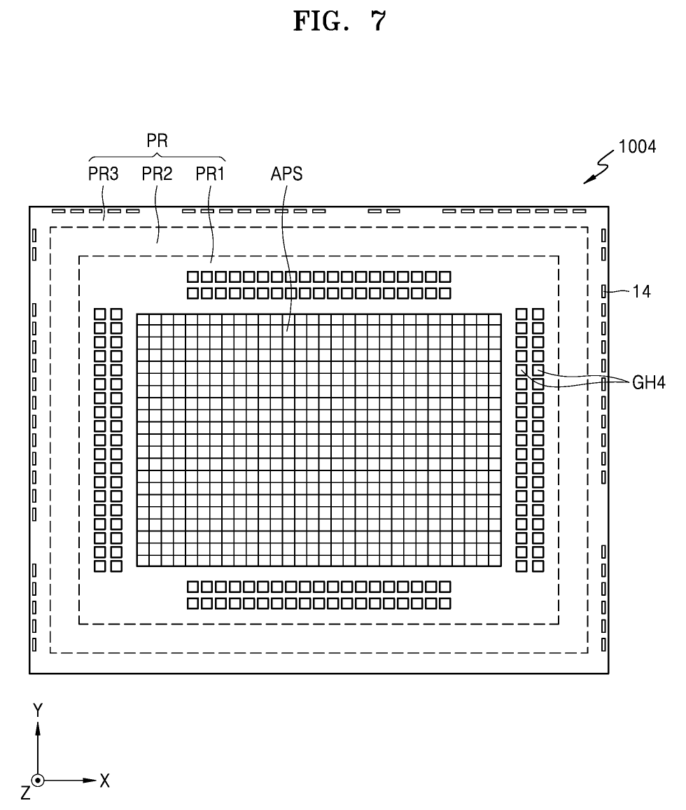

Referring to FIG. 7, multiple holes GH4 formed in an optical black region PR1 of an image sensor 1004 may have a quadrangle cross-sectional shape.

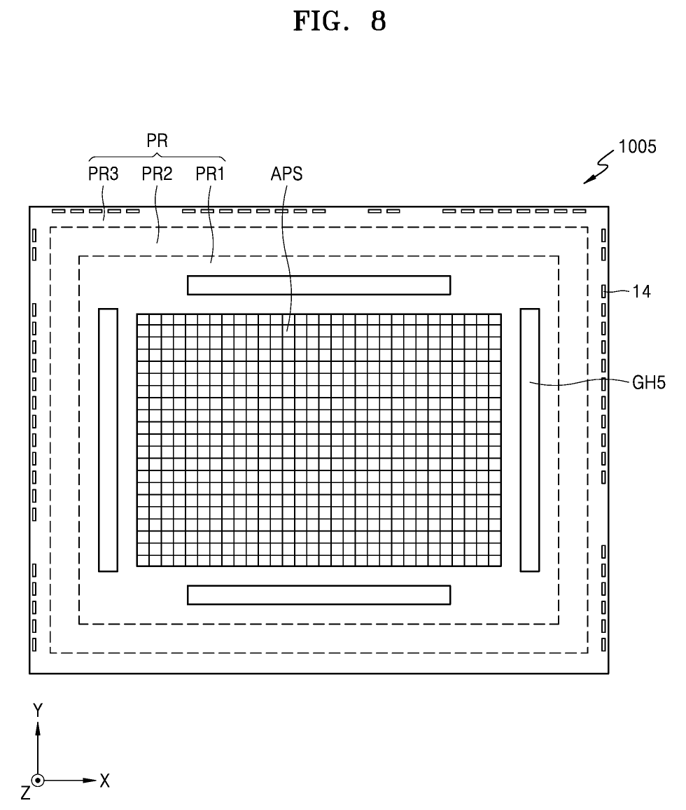

Referring to FIG. 8, an image sensor 1005 may have multiple holes GH5 each having a stripe shape and being formed in the optical black region PR1. The multiple holes GH5 may each face one of four sides of a quadrangle shape of an active pixel sensor region APS.

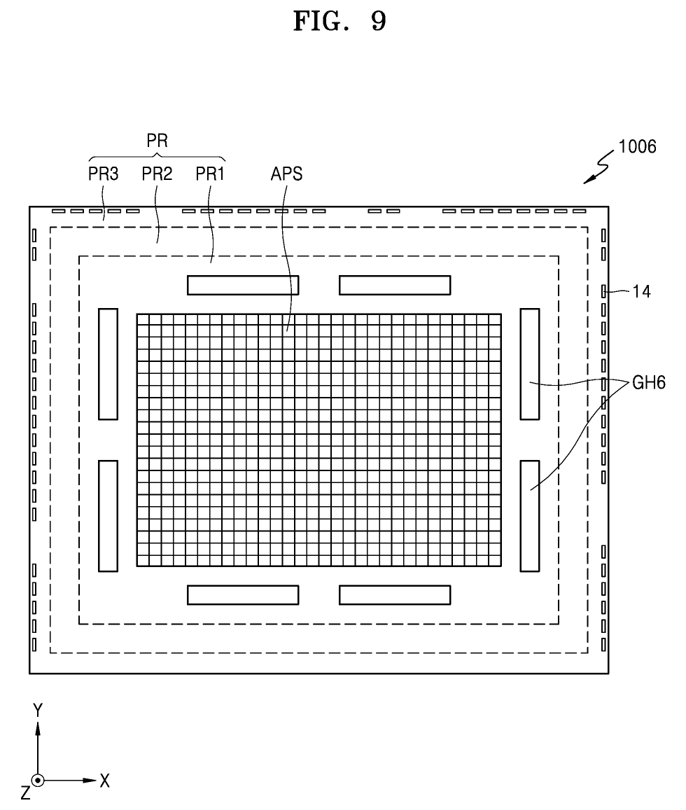

Referring to FIG. 9, an image sensor 1006 may include multiple holes GH6, each having a stripe shape and being formed in an optical black region PR1. Each of four sides of a quadrangle shape of an active pixel sensor region APS may face two holes GH6, and the two holes GH6 may each have a stripe shape and be separated in a length direction.

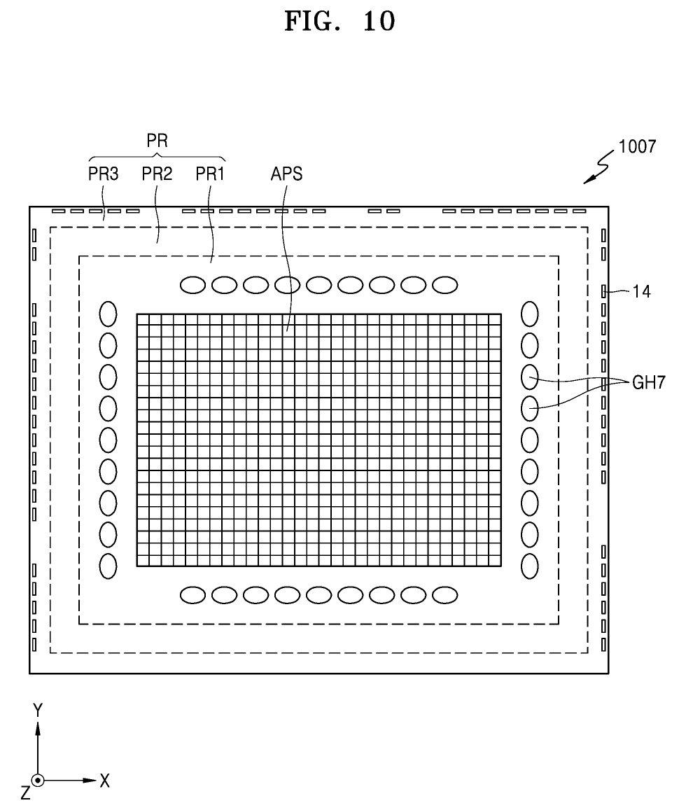

Referring to FIG. 10, an image sensor 1007 may include multiple holes GH7, each having an elliptical shape and being formed in an optical black region PR1.

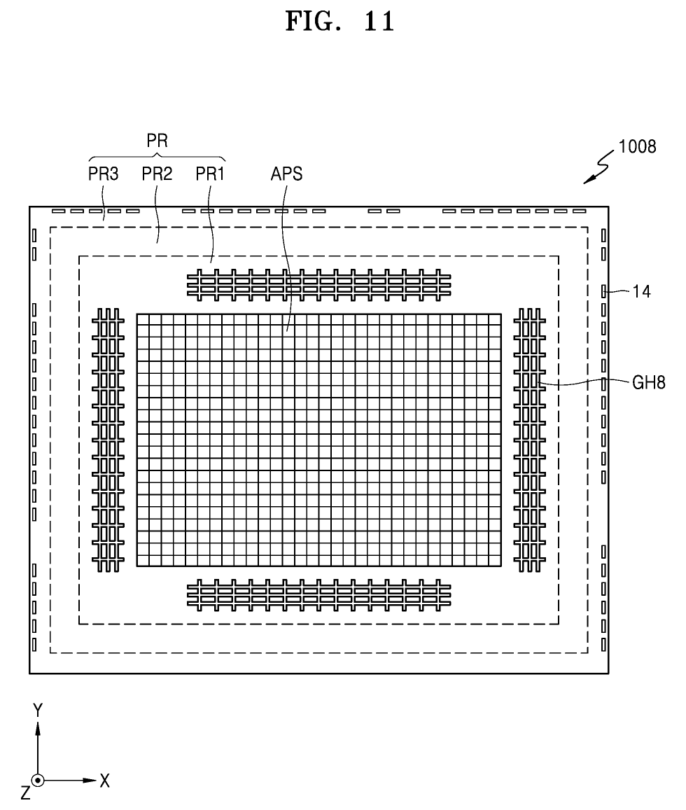

Referring to FIG. 11, an image sensor 1008 may include multiple holes GH8, each having a grid pattern shape and being formed in an optical black region PR1.

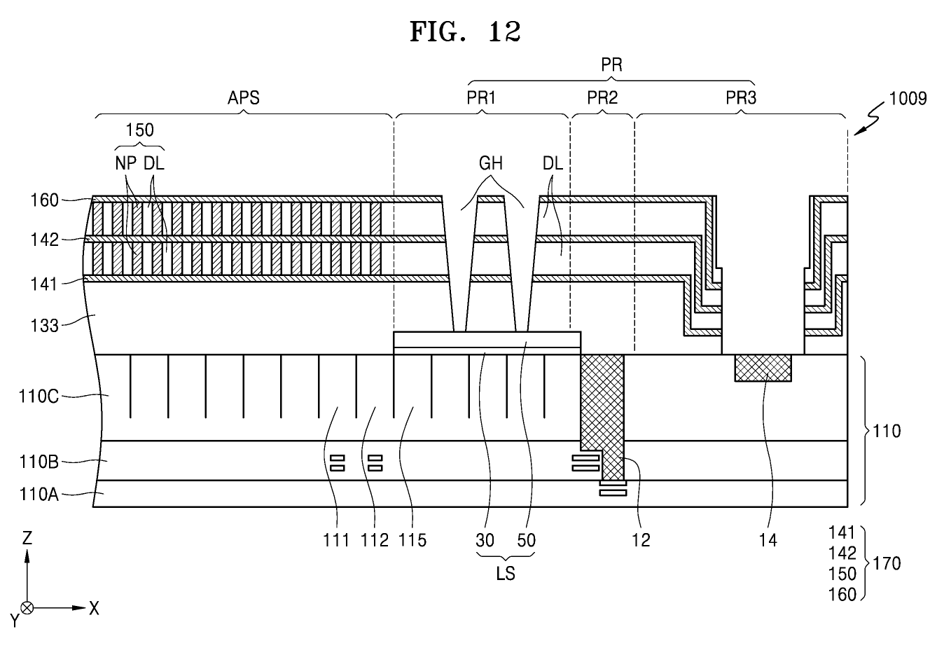

FIG. 12 is a cross-sectional view of an image sensor according to another embodiment.

FIG. 12 illustrates an image sensor 1009, which may differ from the image sensor 1000 of FIG. 3 in that a planarization layer 133 has a single layer formed of an inorganic material. According to an embodiment, a light-shielding layer LS may include an organic material, and multiple holes GH may be formed at a depth that penetrates an optical-transparent layer 170 and the planarization layer 133 to expose the light-shielding layer LS.

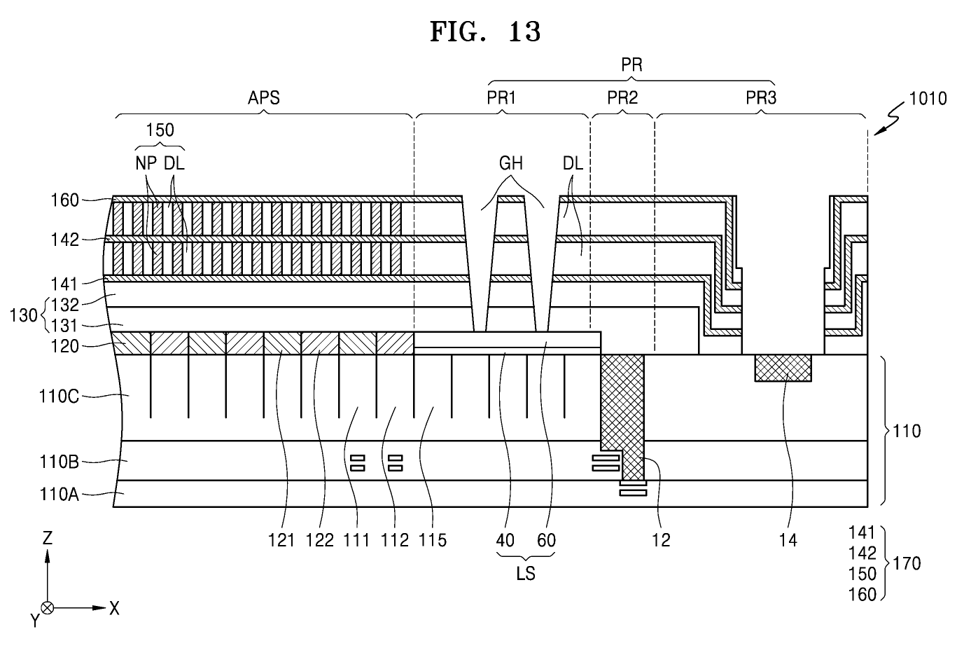

FIG. 13 is a cross-sectional view of an image sensor according to another embodiment.

FIG. 13 illustrates an image sensor 1010, which may differ from the image sensor 1002 of FIG. 5 in that a color filter array layer 120 is further provided in an active pixel sensor region APS.

Although a color filter array layer 120 may be omitted in an embodiment where color separation is made by a meta-optical element 150, the color filter array layer 120 may be provided to further increase color purity.

The color filter array layer 120 may include multiple color filters 121 and 122 arranged two-dimensionally in the first direction and the second direction.

The multiple color filters 121 and 122 of the color filter array layer 120 may each be formed of, for example, an organic polymer material, and may include, but is not limited to, a colorant, a binder resin, and a polymer photoresist. The color filter 121 may include a green organic dye or a green organic pigment as a colorant, and the color filter 122 may include a blue organic dye or a blue organic pigment as a colorant.

According to an embodiment, the color filter array layer 120 may further include a color filter including a red organic dye or a red organic pigment, and may further include a black matrix arranged at a boundary between the multiple color filters 121 and 122. The black matrix may include, for example, carbon black.

Multiple holes GH formed in an optical black region PR1 may each have a depth that penetrates an optical-transparent layer, a second planarization layer 132, and a first planarization layer 131 to expose a first planarization layer 131 and a light-shielding layer LS.

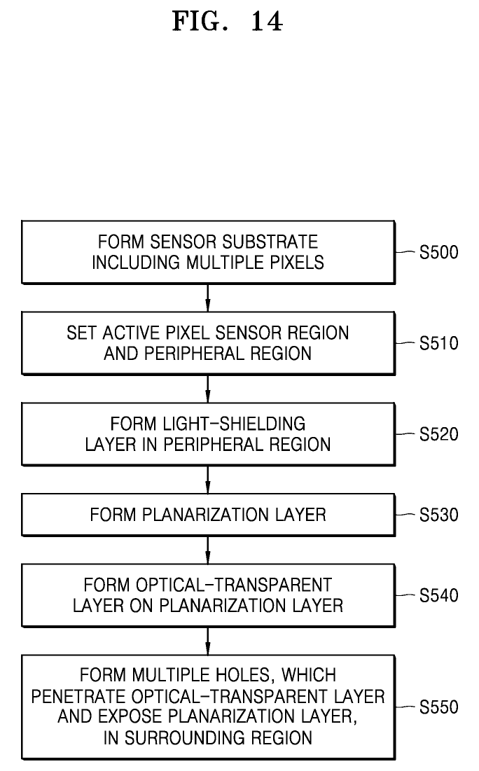

FIG. 14 is a flowchart schematically illustrating a method of manufacturing an image sensor, according to an embodiment.

Referring to FIG. 14, the method of manufacturing an image sensor may include operation S500 of forming a sensor substrate including multiple pixels that detect light, and operation S510 of setting an active pixel sensor region and a peripheral region. The active pixel sensor region and the peripheral region are as described with reference to FIGS. 2 and 3. The two operations are not limited to the sequence illustrated in FIG. 14, and the region setting may be performed in an operation of forming a sensor substrate.

In operation S520, the method may include forming a light-shielding layer in the peripheral region. For example, the light-shielding layer may be first formed in the entire region on the sensor substrate and then be patterned into a preset pattern. However, the disclosure is not limited thereto. For example, after the light-shielding layer is formed in the active pixel sensor region and the peripheral region, the light-shielding layer in the active pixel sensor region may be removed.

In operation S530, the method may include forming, a planarization layer on the sensor substrate. The planarization region may extend from the active pixel sensor region to the peripheral region. The planarization region may be provided on the light-shielding layer. For example, the planarization region may cover the light-shielding layer. As described above, the planarization layer may be formed in multiple layers including a layer including an organic material and a layer including an inorganic material. Alternatively, the planarization layer may include only a layer including an inorganic material.

According to an embodiment, before the planarization layer is formed, a color filter array layer may be formed in the active pixel sensor region on the sensor substrate.

In operation S540, the method may include forming an optical-transparent layer on the planarization layer. The optical-transparent layer may include one or more dielectric materials formed in the active pixel sensor region and the peripheral region, and may include a meta-optical element including multiple nanostructures in a region corresponding to the active pixel sensor region.

According to an embodiment, before the optical-transparent layer is formed, a part of the planarization layer may be removed. For example, a part of the planarization layer at a position which is to be a contact pad region of the peripheral region may be etched, in the planarization layer formed across a peripheral area from the active pixel sensor region. An etching process of exposing a sensor substrate may be performed to form multiple contact pads in the contact pad region, and when etching an organic material together with a dielectric material, a defect may occur due to a difference in etching rate as described above. That is, because an etching rate of a dielectric material included in the optical-transparent layer is less than an etching rate of an organic material included in the planarization layer, a defect that a structure around the contact pad collapses may occur in a contact pad region.

In operation S550, the method may include forming multiple holes in the optical-transparent layer For example, after the optical-transparent layer is formed, multiple holes may be formed in a surrounding region. For example, the surrounding region may be region surrounding the active pixel sensor region. The multiple holes may penetrate the optical-transparent layer to expose the planarization layer. The shape or depth of each of the multiple holes may change as in the embodiments described above.

According to an embodiment, the operation S550 of forming the multiple holes may be performed before or after a contact pad in the contact pad region is formed in the peripheral region.

Image sensors 1000 to 1010 according to the embodiments may each configure a camera module together with module lenses of various performances, and may be utilized in various electronic devices.

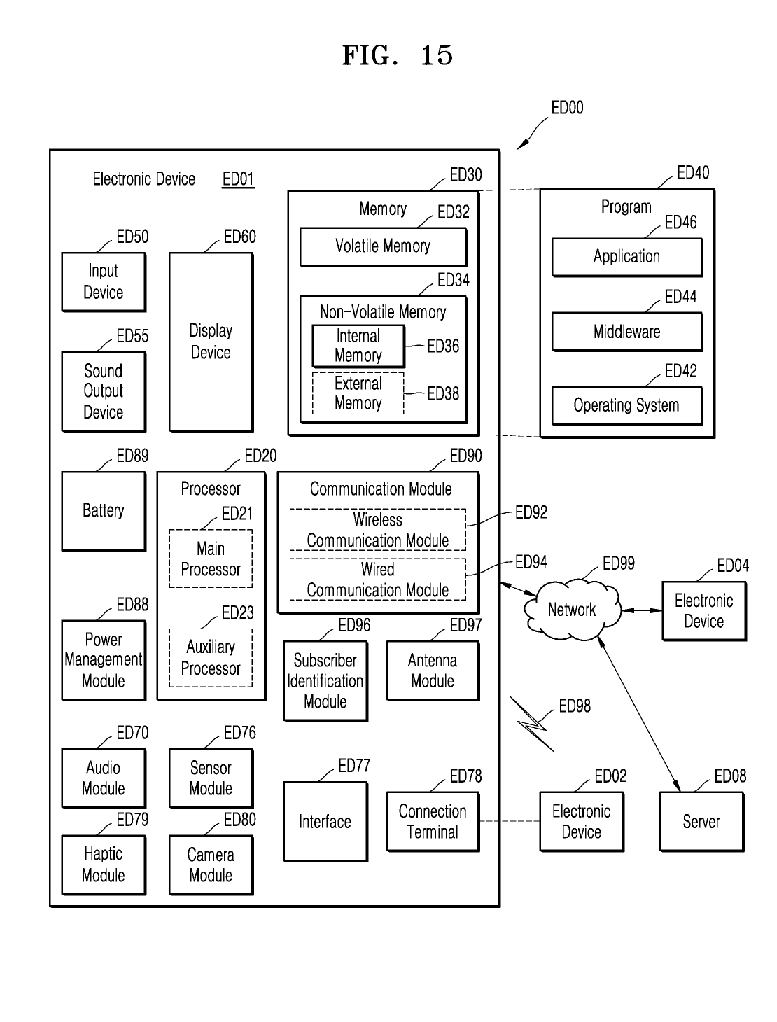

FIG. 15 is a block diagram schematically illustrating an electronic device including an image sensor according to the embodiment. Referring to FIG. 15, in a network environment ED00, an electronic device ED01 may communicate with another electronic device ED02 through a first network ED98 (a short-range wireless communication network or so on) or may communicate with another electronic device ED04 and/or a server ED08 through a second network ED99 (a long-distance wireless communication network or so on). The electronic device ED01 may communicate with the electronic device ED04 through the server ED08. The electronic device ED01 may include a processor ED20, a memory ED30, an input device ED50, a sound output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. Some (the display device ED60 and so on) of the components may be omitted from the electronic device ED01, or other components may be added to the electronic device ED01. Some of the components may be integrated into one circuit. For example, the sensor module ED76 (a fingerprint sensor, an iris sensor, an illuminance sensor, or so on) may be embedded in the display device ED60 (a display or so on).

The processor ED20 may execute software (such as a program ED40) to control one or more other components (hardware, software components, and so on) of the electronic device ED01 connected to the processor ED20 and may perform various data processing or arithmetic. The processor ED20 stores commands and/or data received from other components (the sensor module ED76, the communication module ED90, and so on) in a volatile memory ED32 and process the commands and/or the data stored in the volatile memory ED32 and store resulting data in a non-volatile memory ED34 as part of data processing or arithmetic. The processor ED20 may include a main processor ED21 (a central processing unit, an application processor, or so on) and an auxiliary processor ED23 (a graphics processing unit, an image signal processor, a sensor hub processor, a communication processor, or so on) that may operate independently or together therewith. The auxiliary processor ED23 may use less power than the main processor ED21 and may perform a specialized function.

The auxiliary processor ED23 may control functions and/or states related to some components (the display device ED60, the sensor module ED76, the communication module ED90, and so on) of the electronic device ED01 on behalf of the main processor ED21 while the main processor ED21 is in an inactive state (sleep state), or together with the main processor ED21 while the main processor ED21 is in an active state (the application execution state). The auxiliary processor ED23 (an image signal processor, a communication processor, or so on) may be implemented as part of another component (the camera module ED80, the communication module ED90, or so on) functionally related thereto.

The memory ED30 may store a variety of data required by components (the processor ED20, the sensor module ED76, and so on) of the electronic device ED01. Data may include, for example, input data and/or output data for software (such as the program ED40) and commands related thereto. The memory ED30 may include the volatile memory ED32 and/or the non-volatile memory ED34.

The program ED40 may be stored as software in the memory ED30 and may include an operating system ED42, middleware ED44, and/or an application ED46.

The input device ED50 may receive commands and/or data to be used in components (the processor ED20 and so on) of the electronic device ED01 from an exterior (a user or so on) of the electronic device ED01. The input device ED50 may include a remote controller, a microphone, a mouse, a keyboard, and/or a digital pen (a stylus pen or so on).

The sound output device ED55 may output a sound signal to the exterior of the electronic device ED01. The sound output device ED55 may include a speaker and/or a receiver. The speaker may be used for general purposes such as multimedia playback or recording playback, and the receiver may be used to receive incoming calls. The receiver may be integrated into the speaker as part of the speaker or may be implemented as an independent separate device.

The display device ED60 may visually provide information to the exterior of the electronic device ED01. The display device ED60 may include a control circuit for controlling a display, a hologram device, or a projector and a corresponding device. The display device ED60 may include touch circuitry configured to detect a touch, and/or sensor circuitry configured to measure the intensity of force generated by the touch (a pressure sensor or so on).

The audio module ED70 may convert audio into an electrical signal or may convert an electrical signal into audio. The audio module ED70 may acquire audio through the input device ED50 or may output audio through a speaker and/or headphones of the sound output device ED55, and/or another electronic device (the electronic device ED02) directly or wirelessly connected to the electronic device ED01.

The sensor module ED76 may detect an operation state (power, temperature, and so on) of the electronic device ED01 or an external environmental state (user state or so on) and may generate an electrical signal and/or a data value corresponding to the detected state. The sensor module ED76 may include a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface ED77 may support one or more designated protocols that may be used for the electronic device ED01 to be connected directly or wirelessly to another electronic device (the electronic device ED02 or so on). The interface ED77 may include a high-definition multimedia interface (HDMI), a Universal Serial Bus (USB) interface, a secure digital (SD) card interface, and/or an audio interface.

A connection terminal ED78 may include a connector through which the electronic device ED01 may be physically connected to another electronic device (for example, the electronic device ED02). The connection terminal ED78 may include an HDMI connector, a USB connector, an SD card connector, and/or an audio connector (a headphones connector or so on).

The haptic module ED79 may convert an electrical signal into a mechanical stimulus (vibration, movement, or so on) or an electrical stimulus that a user may perceive through a tactile or motor sense. The haptic module ED79 may include a motor, a piezoelectric effect element, and/or an electrical stimulation element.

The camera module ED80 may capture a still image and a video. The camera module ED80 may include a lens assembly including one or more lenses, the image sensor 1000, image signal processors, and/or flashes. The image sensor 1000 may be any one of the image sensors 1000 to 1010 of the various embodiments described above. The lens assembly included in the camera module ED80 may collect light emitted from an object to be imaged.

The power management module ED88 may manage power supplied to the electronic device ED01. The power management module ED88 may be implemented as part of a power management integrated circuit (PMIC).

The battery ED89 may supply power to configuration elements of the electronic device ED01. The battery ED89 may include a non-rechargeable primary cell, a rechargeable secondary cell, and/or a fuel cell.

The communication module ED90 may establish a direct (wired) communication channel and/or a wireless communication channel between the electronic device ED01 and another electronic device (the electronic device ED02, the electronic device ED04, the server ED08, or so on), and may support communication through the established communication channel. The communication module ED90 may operate independently of the processor ED20 (application processor or so on) and may include one or more communication processors that support direct communication and/or wireless communication. The communication module ED90 may include a wireless communication module ED92 (a cellular communication module, a short-range wireless communication module, a global navigation satellite system (GNSS) communication module, or so on) and/or a wired communication module ED94 (a local area network (LAN) communication module, a power line communication module, or so on). A corresponding communication module among these communication modules may communicate with another electronic device through the first network ED98 (a short-range communication network such as Bluetooth, WiFi Direct, or infrared data association (IrDA)) or the second network ED99 (a telecommunication network such as a cellular network, the Internet, or a computer network (a LAN, a wide area network (WAN), or so on). Various types of these communication modules may be integrated into one configuration element (a single chip or so on) or may be implemented as multiple separate configuration elements (multiple chips). The wireless communication module ED92 may check and authenticate the electronic device ED01 in a communication network such as the first network ED98 and/or the second network ED99 by using subscriber information (international mobile subscriber identifier (IMSI) and so on) stored in the subscriber identification module ED96.

The antenna module ED97 may transmit a signal and/or power to the outside (other electronic devices or so on) or may receive a signal from the outside. An antenna may include a radiator made of a conductive pattern formed on a substrate (a printed circuit board (PCB) or so on). The antenna module ED97 may include one or more antennas. In an example case in which multiple antennas are included, an antenna suitable for a communication method used in a communication network such as the first network ED98 and/or the second network ED99 may be selected from among the multiple antennas by the communication module ED90. A signal and/or power may be transmitted or received between the communication module ED90 and other electronic devices through the selected antenna. In addition to the antenna, other components (a radio frequency integrated circuit (RFIC) and so on) may be included as some of the antenna module ED97.

Some of the configuration elements may be connected to each other through a communication method (a bus, general purpose input and output (GPIO), serial peripheral interface (SPI), mobile industry processor interface (MIPI), or so on) between peripheral devices and may exchange signals (commands, data, and so on).

A command or data may be transmitted or received between the electronic device ED01 and the electronic device ED04, which is external, through the server ED08 connected to the second network ED99. The other electronic devices ED02 and ED04 may be the same devices as or different types of devices from the electronic device ED01. All or some of operations performed by the electronic device ED01 may be performed by one or more of the other electronic devices ED02, ED04, and ED08. In an example case in which the electronic device ED01 needs to perform a function or service, the electronic device may request one or more other electronic devices to perform the function or part or all of the service, instead of performing the function or service by itself. One or more other electronic devices that receive a request may perform an additional function or service related to the request and may transmit a performance result to the electronic device ED01. To this end, cloud computing technology, distributed computing technology, and/or client-server computing technology may be used.

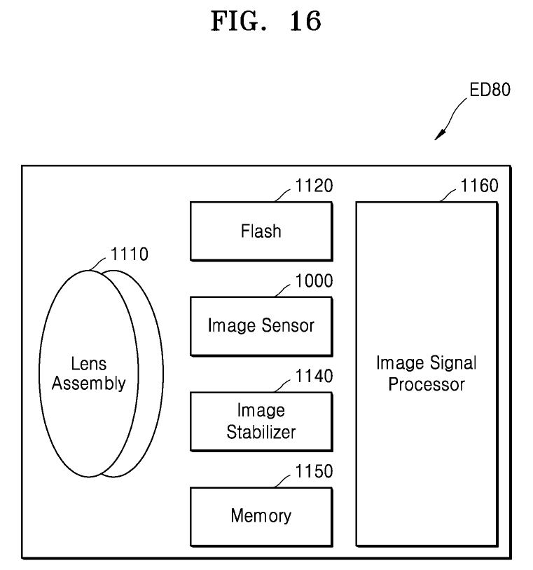

FIG. 16 is a block diagram illustrating the camera module ED80 included in the electronic device ED01 of FIG. 15. Referring to FIG. 16, the camera module ED80 may include a lens assembly 1110, a flash 1120, an image sensor 1000, an image stabilizer 1140, a memory 1150 (a buffer memory or so on), and/or an image signal processor 1160. The lens assembly 1110 may collect light emitted from a subject that is an image capturing target. The camera module ED80 may include multiple lens assemblies 1110, and in this case, the camera module ED80 may serve as a dual camera, a 360-degree camera, or a spherical camera. Some of the multiple lens assemblies 1110 may have the same lens property (an angle of view, a focal length, an auto focus, an F number, optical zoom, and so on) or may have different lens properties. The lens assembly 1110 may include a wide-angle lens or a telephoto lens.

The flash 1120 may emit light used to enhance light emitted or reflected from an object. Flash 1120 may emit visible light or infrared light. The flash 1120 may include one or more light emitting diodes (LEDs) (a red-green-blue (RGB) LED, a white LED, an infrared LED, an ultraviolet LED, and so on), and/or a Xenon Lamp. The image sensor 1000 may be one of the image sensors 1000 to 1010 described above, and may convert the light emitted or reflected from a subject and transferred through the lens assembly 1110 into an electrical signal, thereby obtaining an image corresponding to the subject.

According to an embodiment, based on (or in response to) movement of the camera module ED80 or the electronic device ED01 including the camera module ED80, the image stabilizer 1140 may move one or more lenses included in the lens assembly 1110 or the image sensor 1000 in a certain direction, or may control (adjust read-out timing or so on) operating characteristics of the image sensor 1000 to reduce a negative influence of the movement. The image stabilizer 1140 may detect movement of the camera module ED80 or the electronic device ED01 by using a gyro sensor or an acceleration sensor located inside or outside the camera module ED80. The image stabilizer 1140 may be implemented in an optical type.

The memory 1150 may store some or all data of images acquired by the image sensor 1000 to perform a subsequent image processing operation. In an example case in which multiple images are acquired at a high speed, the acquired original data (Bayer-patterned data, high-resolution data, and so on) is stored in the memory 1150, only low-resolution images are displayed, and then original data of a selected (selected by a user or so on) image is transmitted to the image signal processor 1160. The memory 1150 may be integrated into the memory ED30 of the electronic device ED01 or may be configured as a separate memory that independently operates.

The image signal processor 1160 may acquire images by using electrical signals output from the image sensor 1000. For example, the image signal processor 1160 may directly perform a part of the image processing in conjunction with the image sensor 1000. Also, the image sensor 1000 may be requested to provide image data of a certain format according to a format of the acquired image data.

Also, the image signal processor 1160 may perform additional image processing for an image acquired by the image sensor 1000 or image data stored in the memory 1150. The image processing may include generation of a depth map, three-dimensional modeling, generation of a panorama, extraction of feature points, image synthesizing, and/or image compensation (noise reduction, resolution adjustment, brightness adjustment, and blurring), sharpening, softening, and so on. The image signal processor 1160 may control (controls exposure time, controls read-out timing, and so on) components (for example, the image sensor 1000 and so on) included in the camera module ED80.

An image processed by the image signal processor 1160 may be stored back in the memory 1150 for further processing or may be provided to external components (the memory ED30, the display device ED60, the electronic device ED02, the electronic device ED04, the server ED08, and so on) of the camera module ED80. The image signal processor 1160 may be integrated into the processor ED20 or may be configured as a separate processor that operates independently of the processor ED20. In an example case in which the image signal processor 1160 is configured as a processor independent of the processor ED20, an image processed by the image signal processor 1160 may be subjected to additional image processing by the processor ED20 and then displayed on the display device ED60.

Also, the image signal processor 1160 may independently receive two output signals from adjacent photodetector cells within each pixel or sub-pixel of the image sensor 1000 and generate an auto-focus signal from a difference between the two output signals. The image signal processor 1160 may control the lens assembly 1110 based on the auto-focus signal such that the focus of the lens assembly 1110 is accurately aligned with a surface of the image sensor 1000.

The electronic device ED01 may further include one or more camera modules, each having different properties or functions. The one or more camera modules may each have a configuration that is similar to the camera module ED80 of FIG. 16, and an image sensor included in the camera module may be implemented as a CCD sensor and/or a CMOS sensor and may include one or more sensors selected from image sensors with different properties, such as an RGB sensor, a black and white (BW) sensor, an infrared (IR) sensor, or an ultraviolet (UV) sensor. In this case, one of the multiple camera modules ED80 may include a wide-angle camera, and each of the others may include a telephoto camera. Similarly, one of the multiple camera modules ED80 may include a front camera and each of the others may include a rear camera.

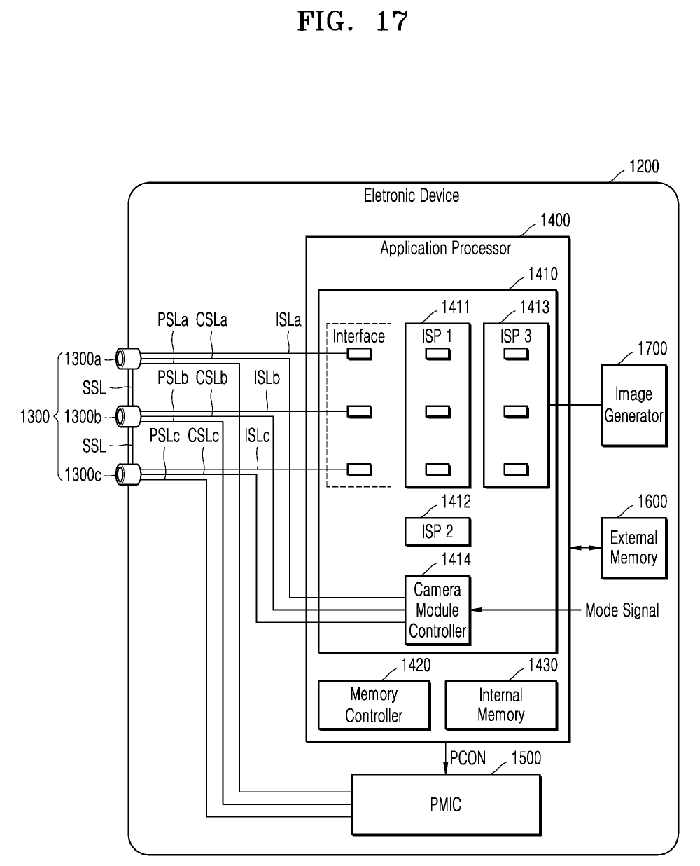

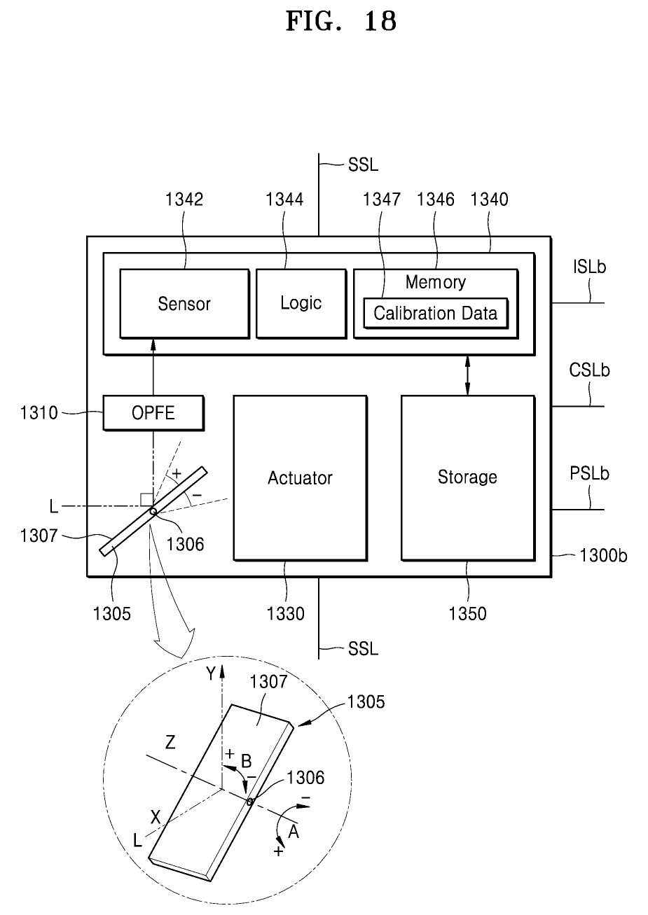

FIG. 17 is a block diagram of an electronic device including multiple camera modules, and FIG. 18 is a detailed block diagram of one camera module included in the electronic device of FIG. 17.

Referring to FIG. 17, an electronic device 1200 may include a camera module group 1300, an application processor 1400, a power management integrated circuit (PMIC) 1500, an external memory 1600, and an image generator 1700.

The camera module group 1300 may include multiple camera modules 1300a, 1300b, and 1300c. Although FIG. 17 illustrates an embodiment in which three camera modules 1300a, 1300b, and 1300c are arranged, the embodiment is not limited thereto. In some embodiments, the camera module group 1300 may be modified to include only two camera modules. Also, in some embodiments, the camera module group 1300 may also be modified to include n camera modules (n is a natural number greater than or equal to 4).

Hereinafter, a detailed configuration of the camera module 1300b is described in more detail with reference to FIG. 17, and the description below may be equally applied to the other camera modules 1300a and 1300c according to an embodiment.

Referring to FIG. 17, the camera module 1300b may include a prism 1305, an optical path folding element (hereinafter, referred to as "OPFE") 1310, an actuator 1330, an image sensing device 1340, and a storage 1350.

The prism 1305 may include a reflective surface 1307 of a light reflective material to change a path of light L that is incident from the outside.

In some embodiments, the prism 1305 may change the path of light L that is incident in a first direction (the X direction) to a second direction (the Y direction) perpendicular to the first direction (the X direction). Also, the prism 1305 may rotate the reflective surface 1307 of the light-reflecting material in an A direction around a central axis 1306 or rotate the central axis 1306 in a B direction to change the path of the light L, which is incident in the first direction (the X direction), to the second direction (the Y direction) that is perpendicular to the first direction. At this time, the OPFE 1310 may also move in the third direction (the Z direction), which is perpendicular to the first direction (the X direction) and the second direction (the Y direction).

In some embodiments, as illustrated in FIG. 18, the greatest rotation angle of the prism 1305 in the A direction may be less than or equal to 15 degrees in the +A direction and greater than or equal to 15 degrees in the -A direction, but the embodiments are not limited thereto.

In some embodiments, the prism 1305 may move in the +B or -B direction by about 20 degrees, an angle between 10 degrees and 20 degrees, or an angle between 15 degrees and 20 degrees, wherein the angle of movement may be the same angle in the +B or -B direction or may move to a substantially similar angle within a range of about 1 degree.

In some embodiments, the prism 1305 may move the reflective surface 1307 of a light-reflecting material in the third direction (for example, the Z direction) that is parallel to an extension direction of the central axis 1306.

The OPFE 1310 may include, for example, m (m is a natural number) optical lenses. The m optical lenses may move in the second direction (the Y direction) to change an optical zoom ratio of the camera module 1300b. In an example case in which a basic optical zoom ratio of the camera module 1300b is referred to as Z, and in an example case in which m optical lenses included in the OPFE 1310 are moved, the optical zoom ratio of the camera module 1300b may be changed to an optical zoom ratio of 3Z, 5Z, or 10Z or more.

The actuator 1330 may move the OPFE 1310 or the m optical lens (hereinafter, referred to as an optical lens) to a certain position. For example, the actuator 1330 may adjust a position of the optical lens such that an image sensor 1342 is located at a focal length of the optical lens for accurate detection.

The image sensing device 1340 may include the image sensor 1342, a control logic 1344, and a memory 1346. The image sensor 1342 may detect an image of a detection target by using the light L provided through the optical lens. The control logic 1344 may control all operations of the camera module 1300b. For example, the control logic 1344 may control an operation of the camera module 1300b based on (or in response to) a control signal transmitted through a control signal line CSLb.

The memory 1346 may store information required for the operation of the camera module 1300b, such as calibration data 1347. The calibration data 1347 may include information required for generating image data by using the light L that is incident from the outside through the camera module 1300b. The calibration data 1347 may include, for example, information on the degree of rotation described above, information on a focal length, information on an optical axis, and so on. In an example case in which the camera module 1300b is implemented in the form of a multi-state camera in which a focal length changes depending on positions of the optical lens, the calibration data 1347 may include a focal length value for each position (or for each state) of the optical lens and information on auto focusing.

The storage 1350 may store the image data detected by the image sensor 1342. The storage 1350 may be arranged outside the image sensing device 1340 and may be implemented in the form in which the storage 1350 is stacked with the sensor chip constituting the image sensing device 1340. In some embodiments, the storage 1350 may include an electrically erasable programmable read-only memory (EEPROM), but the embodiments are not limited thereto.

Referring to FIGS. 17 and 18, in some embodiments, the multiple camera modules 1300a, 1300b, and 1300c may each include the actuator 1330. Accordingly, the multiple camera modules 1300a, 1300b, and 1300c may each include identical or different calibration data 1347 according to an operation of the actuator 1330 included in the camera.

In some embodiments, one camera module (for example, 1300b) among the multiple camera modules 1300a, 1300b, and 1300c may be a folded lens-type camera module including the prism 1305 and the OPFE 1310 described above, and the other camera modules (for example, 1300a and 1300b) may be vertical-type camera modules that do not include the prism 1305 and the OPFE 1310, but the embodiments are not limited thereto.

In some embodiments, one camera module (for example, 1300c) among the multiple camera modules 1300a, 1300b, and 1300c may be a vertical-type depth camera that extracts depth information by using, for example, infrared rays (IRs).

In some embodiments, at least two camera modules (for example, 1300a and 1300b) among the multiple camera modules 1300a, 1300b, and 1300c may have different fields of view. In this case, for example, optical lenses of at least two camera modules (for example, 1300a and 1300b among the multiple camera modules 1300a, 1300b, and 1300c may be different from each other, but embodiments are not limited thereto.

Also, in some embodiments, the fields of view of the multiple camera modules 1300a, 1300b, and 1300c may be different from each other. In this case, optical lenses included in the multiple camera modules 1300a, 1300b, and 1300c may also be different from each other, but embodiments are not limited thereto.

In some embodiments, the multiple camera modules 1300a, 1300b, and 1300c may be physically separated from each other. That is, instead that a detection region of one image sensor 1342 is divided by the multiple camera modules 1300a, 1300b, and 1300c, an independent image sensor 1342 may be arranged inside each of the multiple camera modules 1300a, 1300b, and 1300c.

Referring again to FIG. 17, the application processor 1400 may include an image processing device 1410, a memory controller 1420, and an internal memory 1430. The application processor 1400 may be separated from the multiple camera modules 1300a, 1300b, and 1300c. For example, the application processor 1400 and multiple camera modules 1300a, 1300b, and 1300c may be implemented in different semiconductor chips.

The image processing device 1410 may include multiple image processors 1411, 1412, and 1413, and a camera module controller 1414.

The image data generated by the multiple camera modules 1300a, 1300b, and 1300c may be provided to the image processing device 1410 through image signal lines ISLa, ISLb, and ISLc, which are separated from each other. Such image data transmission may be performed by using a camera serial interface (CSI) based on, for example, mobile industry processor interface (MIPI), but embodiments are not limited thereto.

The image data transmitted to the image processing device 1410 may be stored in the external memory 1600 before being transmitted to the image processors 1411 and 1412. The image data stored in the external memory 1600 may be provided to the image processor 1411 and/or the image processor 1412. The image processor 1411 may correct the received image data to generate a video. The image processor 1412 may correct the received image data to generate a still image. For example, the image processors 1411 and 1412 may perform preprocessing operations, such as color correction and gamma correction, on the image data.

The image processor 1411 may include sub-processors. In an example case in which the number of sub-processors is equal to the number of camera modules 1300a, 1300b, and 1300c, the sub-processors may each process image data received from one camera module. In an example case in which the number of sub-processors is less than the number of camera modules 1300a, 1300b, and 1300c, at least one of the sub-processors may process the image data received from the multiple camera modules through a timing sharing process. The image data processed by the image processor 1411 and/or the image processor 1412 may be stored in the external memory 1600 before being transmitted to the image processor 1413. The image data stored in the external memory 1600 may be transmitted to the image processor 1412. The image processor 1412 may perform postprocessing operations, such as noise correction and sharpening correction, on the image data.

The image data processed by the image processor 1413 may be provided to the image generator 1700. The image generator 1700 may generate a final image by using the image data received from the image processor 1413 according to the image generating information or a mode signal.

Specifically, the image generator 1700 may generate an output image by merging at least some of the image data generated by the multiple camera modules 1300a, 1300b, and 1300c having different fields of view according to the image generating information or the mode signal. Also, the image generator 1700 may generate an output image by selecting one of pieces of the image data generated by the multiple camera modules 1300a, 1300b, and 1300c having different fields of view according to the image generating information or the mode signal.

In some embodiments, the image generating information may include a zoom signal (or a zoom factor). Also, in some embodiments, the mode signal may be a signal based on a mode selected by, for example, a user.

In an example case in which the image generation information is a zoom signal (a zoom factor) and the multiple camera modules 1300a, 1300b, and 1300c have different observation views (fields of view), the image generator 1700 may perform different operations depending on types of the zoom signal. In an example case in which the zoom signal is a first signal, the image data output from the camera module 1300a may be merged with the image data output from the camera module 1300c, and then an output image may be generated by using the merged image signal and the image data output from the camera module 1300b that is not used for merging. In an example case in which the zoom signal is a second signal different from the first signal, the image generator 1700 may select one of pieces of the image data output from multiple camera modules 1300a, 1300b, and 1300c without performing merging of the image data and may generate an output image. However, embodiments are not limited thereto, and a method of processing the image data may be modified and implemented as needed.

The camera module controller 1414 may provide control signals respectively to the multiple camera modules 1300a, 1300b, and 1300c. The control signals generated by the camera module controller 1414 may be provided to the multiple camera modules 1300a, 1300b, and 1300c respectively through control signal lines CSLa, CSLb, and CSLc that are separated from each other.

In some embodiments, the control signals provided from the camera module controller 1414 to the multiple camera modules 1300a, 1300b, and 1300c may each include mode information according to a mode signal. Based on the mode information, the multiple camera modules 1300a, 1300b, and 1300c may operate in a first operation mode and a second operation mode in relation to a detection speed.

In the first operation mode, the multiple camera modules 1300a, 1300b, and 1300c may each generate (for example, generate an image signal at a first frame rate) an image signal at a first speed, encode (for example, encode an image signal at a second frame rate higher than the first frame rate) the image signal at a second speed higher than the first speed, and transmit the encoded image signal to the application processor 1400. In this case, the second speed may be less than or equal to 30 times the first speed.

The application processor 1400 may store the received image signal, that is, the encoded image signal, in the memory 1430 provided internally or in the storage 1600 external to the application processor 1400, and then read the encoded image signal from the memory 1430 or the storage 1600, decode the encoded image signal, and display the image data generated based on the decoded image signal. For example, the image processors 1411 and 1412) of the image processing device 1410 may perform decoding and may also perform image processing on the decoded image signal.

The multiple camera modules 1300a, 1300b, and 1300c may generate (for example, generate image signals at a third frame rate lower than the first frame rate) image signals at a third rate lower than the first rate in the second operation mode and transmit the image signals to the application processor 1400. The image signals provided to the application processor 1400 may be unencoded signals. The application processor 1400 may perform image processing on the received image signals or store the image signals in the memory 1430 or storage 1600.

The PMIC 1500 may supply power, for example, a power voltage, to each of the multiple camera modules 1300a, 1300b, and 1300c. For example, the PMIC 1500 may supply first power to the camera module 1300a through a power signal line PSLa, supply second power to the camera module 1300b through a power signal line PSLb, and supply third power to the camera module 1300c through a power signal line PSLc, under the control by the application processor 1400.

The PMIC 1500 may generate power corresponding to each of the multiple camera modules 1300a, 1300b, and 1300c based on (of in response to) a power control signal PCON from the application processor 1400, and may also adjust a level of the power. The power control signal PCON may include a power adjustment signal for each operation mode of the multiple camera modules 1300a, 1300b, and 1300c. For example, the operating mode may include a low power mode, and in this case, the power control signal PCON may include information on a camera module operating in the low power mode and a set power level. Levels of the powers provided to the multiple camera modules 1300a, 1300b, and 1300c may be equal to or different from each other. Also, the levels of powers may be dynamically changed.

According to an embodiment, an image sensor includes an active pixel sensor region configured to output a pixel signal for generating an image, and a peripheral region surrounding the active pixel sensor region, wherein the active pixel sensor region and the peripheral region include a sensor substrate including multiple pixels extending in the active pixel sensor region and the peripheral region; an optical-transparent layer arranged over the sensor substrate, separated from the sensor substrate, and including at least one dielectric material; and a planarization layer arranged between the sensor substrate and the optical-transparent layer, wherein, in the active pixel sensor region, the optical-transparent layer includes a meta-optical element including multiple nanostructures, the peripheral region includes a light-shielding layer surrounding the active pixel sensor region between the planarization layer and the sensor substrate, and the peripheral region includes multiple holes penetrating the optical-transparent layer and exposing one of the planarization layer and the light-shielding layer.

The peripheral region may include an optical black region defined by the light-shielding layer, and a contact pad region including a multiple contact pads and surrounding the optical black region, and in the contact pad region, the optical-transparent layer may have a shape having a step difference.

The planarization layer may include a first planarization layer including an organic material, and a second planarization layer arranged on the first planarization layer and including an inorganic material.

Each of the multiple holes may have a depth that penetrates the second planarization layer and the first planarization layer and exposes an upper surface of the light-shielding layer.

The light-shielding layer may include an organic material.

Each of the multiple holes may have a depth that penetrates the second planarization layer and exposes an upper surface of the first planarization layer.

The light-shielding layer may include a first layer including a light-reflecting material and a second layer arranged on the first layer and including a light-absorbing material.

The active pixel sensor region may further include a color filter array layer arranged between the sensor substrate and the first planarization layer.

The light-shielding layer may include a first layer including one of a light-reflecting material and a light-absorbing material and a second layer arranged on the first layer and including a blue filter material.

An optical black region in the peripheral region may be defined by the light-shielding layer, and a total of cross-sectional areas of the multiple holes may be greater than or equal to 5 % of a cross-sectional area of the optical black region and less than or equal to 50 % of the cross-sectional area of the optical black region.

The active pixel sensor region may have a quadrangle shape, and the multiple holes may be formed at positions facing at least two of four sides of the quadrangle shape.

Each of the multiple holes may have one of a circular shape, an oval shape, a square shape, a rectangular shape, and a polygonal shape.

The active pixel sensor region may have a quadrangle shape, and each of the multiple holes may have a stripe shape parallel to one of four sides of the quadrangle shape.

Each of the multiple holes may have a shape of a grid pattern.

The peripheral region may include an optical black region defined by the light-shielding layer, multiple contact pads, and a contact pad region surrounding the optical black region, and the optical-transparent layer in the contact pad region may have a shape having a step difference.

According to an embodiment, a method of manufacturing includes forming a sensor substrate including multiple pixels that detect light, setting a region of the sensor substrate as an active pixel sensor region and a peripheral region surrounding the active pixel sensor region, and forming a light-shielding layer on the sensor substrate in the peripheral region, forming a planarization layer on the sensor substrate to extend from the active pixel sensor region to the peripheral region and cover the light-shielding layer, forming an optical-transparent layer on the planarization layer to include at least one dielectric material, and forming multiple holes, which penetrate the optical-transparent layer and expose one of the planarization layer and the light-shielding layer, in the peripheral region.

The peripheral region may include an optical black region defined as a region where the light-shielding layer is formed, and a contact pad region including multiple contact pads and surrounding the optical black region, and before the forming of the optical-transparent layer, partially removing a portion of the planarization layer which extends to the contact pad region may be performed.

The forming of the planarization layer may include forming a first planarization layer including an organic material, and forming, on the first planarization layer, a second planarization layer including an inorganic material.

Each of the multiple holes may have a depth that penetrates the first planarization layer and the second planarization layer to expose an upper surface of the light-shielding layer, or penetrates the second planarization layer to expose an upper surface of the first planarization layer.

According to an embodiment, an electronic device includes a lens assembly configured to form an optical image of a subject, and an image sensor configured to convert the optical image formed by the lens assembly into an electrical signal, wherein the image sensor includes an active pixel sensor region configured to output a pixel signal for generating an image; and a peripheral region surrounding the active pixel sensor region, the active pixel sensor region and the peripheral region include a sensor substrate including multiple pixels extending in the active pixel sensor region and the peripheral region; an optical-transparent layer arranged over the sensor substrate, separated from the sensor substrate, and including at least one dielectric material; and a planarization layer arranged between the sensor substrate and the optical-transparent layer, wherein, in the active pixel sensor region, the optical-transparent layer includes a meta-optical element including multiple nanostructures, the peripheral region includes a light-shielding layer surrounding the active pixel sensor region between the planarization layer and the sensor substrate, and the peripheral region includes multiple holes penetrating the optical-transparent layer and exposing one of the planarization layer and the light-shielding layer.

According to one or more embodiment, the image sensor described above has multiple holes in a peripheral region surrounding an active pixel sensor region, and thus, defects due to organic gas released from an organic material included in the image sensor may be reduced.

According to one or more embodiment, the image sensor described above may reduce noise transferred from the peripheral region to the active pixel sensor region by the multiple holes.

According to the method of manufacturing an image sensor described above, the image sensor may be improved in image quality by reducing defects due to organic gas or noise transferred to the active pixel sensor region.

Although the image sensor, the method of manufacturing the image sensor, and the electronic device described above are described with reference to the embodiments illustrated in the drawings, these are merely examples, and those skilled in the art will understand that various modifications and equivalent other embodiments may be derived therefrom. Therefore, the disclosed embodiments should be considered illustrative rather than restrictive. The scope of the disclosure is indicated by the claims, not the foregoing description, and all differences within the scope equivalent thereto should be construed as being included in the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An image sensor comprising:
an active pixel sensor region configured to output a pixel signal; and
a peripheral region surrounding the active pixel sensor region;
wherein the active pixel sensor region and the peripheral region comprise:
a sensor substrate comprising a plurality of pixels extending in the active pixel sensor region and the peripheral region;
an optical-transparent layer provided on the sensor substrate, the optical-transparent layer comprising at least one dielectric material; and
a planarization layer provided between the sensor substrate and the optical-transparent layer,
wherein, in the active pixel sensor region, the optical-transparent layer comprises a meta-optical element comprising a plurality of nanostructures, and
wherein the peripheral region comprises:
a light-shielding layer surrounding the active pixel sensor region between the planarization layer and the sensor substrate, and
a plurality of holes penetrating the optical-transparent layer and exposing one of the planarization layer and the light-shielding layer.

2. The image sensor of claim 1,
Wherein the peripheral region further comprises:
an optical black region defined by the light-shielding layer, and
a contact pad region surrounding the optical black region and comprising a plurality of contact pads, and
wherein, in the contact pad region, the optical-transparent layer has a shape having a step difference.

3. The image sensor of claim 1, wherein the planarization layer comprises:
a first planarization layer comprising an organic material, and
a second planarization layer arranged on the first planarization layer and comprising an inorganic material.

4. The image sensor of claim 3, wherein each of the plurality of holes has a depth that penetrates the second planarization layer and the first planarization layer, and
wherein each of the plurality of holes are configured to expose an upper surface of the light-shielding layer.

5. The image sensor of claim 4, wherein the light-shielding layer comprises an organic material.

6. The image sensor of claim 3, wherein each of the plurality of holes has a depth that penetrates the second planarization layer, and
wherein each of the plurality of holes are configured to expose an upper surface of the first planarization layer.

7. The image sensor of claim 3, wherein the light-shielding layer comprises:
a first layer comprising a light-reflecting material, and
a second layer arranged on the first layer and comprising a light-absorbing material.

8. The image sensor of claim 3, wherein the active pixel sensor region further comprises a color filter array layer arranged between the sensor substrate and the first planarization layer.

9. The image sensor of claim 8, wherein the light-shielding layer comprises:
a first layer comprising one of a light-reflecting material and a light-absorbing material, and
a second layer arranged on the first layer and comprising a blue filter material.

10. The image sensor of claim 1, wherein
an optical black region in the peripheral region is defined by the light-shielding layer, and
a total of cross-sectional areas of the plurality of holes is greater than or equal to 5 % of a cross-sectional area of the optical black region and less than or equal to 50 % of the cross-sectional area of the optical black region.

11. The image sensor of claim 1, wherein
the active pixel sensor region has a quadrangle shape, and
the plurality of holes are formed at positions facing at least two of four sides of the quadrangle shape.

12. The image sensor of claim 1, wherein each of the plurality of holes has one of a circular shape, an oval shape, a square shape, a rectangular shape, and a polygonal shape.

13. The image sensor of claim 1, wherein
the active pixel sensor region has a quadrangle shape, and
each of the plurality of holes has a stripe shape parallel to one side of the quadrangle shape.

14. The image sensor of claim 1, wherein each of the plurality of holes has a shape of a grid pattern.

15. The image sensor of claim 1, wherein the plurality of nanostructures are arranged in a plurality of layers with different distances from the sensor substrate.

16. A method of manufacturing an image sensor, the method comprising:
forming a sensor substrate comprising a plurality of pixels, the sensor substrate having an active pixel sensor region and a peripheral region surrounding the active pixel sensor region;
forming a light-shielding layer on the sensor substrate in the peripheral region;
forming a planarization layer on the sensor substrate and the light-shielding layer, the planarization layer extending from the active pixel sensor region to the peripheral region and cover the light-shielding layer;
forming an optical-transparent layer on the planarization layer to comprise at least one dielectric material; and
forming a plurality of holes, which penetrate the optical-transparent layer and expose one of the planarization layer and the light-shielding layer, in the peripheral region.

17. The method of claim 16,
wherein the peripheral region comprises an optical black region defined as a region where the light-shielding layer is formed, and a contact pad region surrounding the optical black region and comprising a plurality of contact pads, and
wherein the method may further include, before the forming of the optical-transparent layer, partially removing a portion of the planarization layer which extends to the contact pad region is performed.

18. The method of claim 16, wherein the forming of the planarization layer comprises:
forming a first planarization layer comprising an organic material; and
forming, on the first planarization layer, a second planarization layer comprising an inorganic material.

19. The method of claim 18, wherein each of the plurality of holes has a depth that penetrates the first planarization layer and the second planarization layer to expose an upper surface of the light-shielding layer, or penetrates the second planarization layer to expose an upper surface of the first planarization layer.

20. An electronic device comprising:
a lens assembly configured to form an optical image of a subject; and
an image sensor configured to convert the optical image formed by the lens assembly into an electrical signal,
wherein the image sensor comprises:
an active pixel sensor region configured to output a pixel signal; and
a peripheral region surrounding the active pixel sensor region,
wherein the active pixel sensor region and the peripheral region comprise:
a sensor substrate comprising a plurality of pixels extending in the active pixel sensor region and the peripheral region;
an optical-transparent layer provided on the sensor substrate, the optical-transparent layer comprising at least one dielectric material; and
a planarization layer provided between the sensor substrate and the optical-transparent layer,
wherein, in the active pixel sensor region, the optical-transparent layer comprises a meta-optical element comprising a plurality of nanostructures, and
wherein the peripheral region comprises:
a light-shielding layer surrounding the active pixel sensor region between the planarization layer and the sensor substrate, and
a plurality of holes penetrating the optical-transparent layer and exposing one of the planarization layer and the light-shielding layer.
